(19) United States
(12) Patent Application Publication
(10) Pub. No.: US 2026/0033166 A1
(43) Pub. Date: Jan. 29, 2026

(54) DISPLAY PANEL, ELECTRONIC DEVICE INCLUDING THE SAME, AND METHOD FOR MANUFACTURING THE DISPLAY PANEL

(71) Applicant: Samsung Display Co., Ltd., Yongin-si (KR)

(72) Inventors: HYUN SUP LEE, Yongin-si (KR); DONGKYUN SEO, Yongin-si (KR); YANG-HO JUNG, Yongin-si (KR)

(21) Appl. No.: 19/263,276

(22) Filed: Jul. 8, 2025

(30) Foreign Application Priority Data
Jul. 26, 2024 (KR) 10-2024-0099240

(51) Int. Cl. H10K 59/124; H10H 29/01; H10H 29/32; H10H 29/41; H10H 29/49; H10K 59/12; H10K 59/121; H10K 59/131; H10K 59/40

(52) U.S. Cl. CPC H10K 59/124; H10H 29/012; H10H 29/32; H10H 29/41; H10H 29/49; H10K 59/1201; H10K 59/1213; H10K 59/131; H10K 59/40

(57) ABSTRACT

A display panel includes a display area, a non-display area adjacent to the display area, a base layer including a first resin layer and a second resin layer defining an upper resin opening, a pad electrode between the first resin layer and the second resin layer, a driving element layer including a barrier layer defining a barrier opening, a data line above the barrier layer, a conductive pattern including a pad conductive portion, an insulating layer defining a connection opening and a main opening, and a bridge conductive pattern, and a display element layer above the second resin layer.

### CROSS-REFERENCE TO RELATED APPLICATION(S)

The present application claims priority to, and the benefit of, Korean Patent Application No. 10-2024-0099240, filed on Jul. 26, 2024, in the Korean Intellectual Property Office, the entire disclosure of which is incorporated herein by reference.

### BACKGROUND

### 1. Field

The present disclosure relates to a display panel, an electronic device including the same, and a method for manufacturing the display panel with improved reliability.

### 2. Description of Related Art

Electronic devices, such as smartphones, tablet computers, notebook computers, car navigation units, and smart televisions, are being developed. The electronic devices include a display device to provide information.

Various types of display devices are being developed to satisfy the user experience (UX) and the user interface (UI). Research to provide a display device with a wide display area and a narrow non-display area are being conducted.

### SUMMARY

The present disclosure provides a display panel with improved reliability due to reduced size of a non-display area.

The present disclosure provides an electronic device including the display panel with reduced non-display area and improved reliability.

The present disclosure provides a method for manufacturing the display panel with reduced non-display area and improved reliability.

Embodiments of the present disclosure provide a display panel including a display area, a non-display area adjacent to the display area, a base layer including a first resin layer overlapping the display area and the non-display area, and a second resin layer above the first resin layer and defining an upper resin opening overlapping the non-display area, a pad electrode between the first resin layer and the second resin layer, overlapping the non-display area, and having a portion of an upper surface exposed through the upper resin opening, a driving element layer including a barrier layer above the second resin layer, and defining a barrier opening overlapping the upper resin opening, a data line above the barrier layer, a conductive pattern including a pad conductive portion in the upper resin opening and contacting the pad electrode, and a data conductive portion contacting the data line, an insulating layer above the conductive pattern, defining a connection opening exposing a portion of the data conductive portion, and defining a main opening overlapping the upper resin opening, and a bridge conductive pattern above the conductive pattern and the insulating layer, contacting the pad conductive portion through the upper resin opening, and contacting the data conductive portion through the connection opening, and a display element layer including a light-emitting element above the second resin layer overlapping the display area, and a transistor electrically connected to the light-emitting element and to the data line, wherein the barrier opening is defined by a protrusion barrier side surface adjacent to the connection opening, and by a main barrier side surface surrounding a portion of the upper resin opening in plan view, wherein the main opening is defined by a protrusion insulating side surface adjacent to the connection opening, and by a main insulating side surface surrounding a portion of the upper resin opening in plan view and overlapping the main barrier side surface in plan view, and wherein the protrusion barrier side surface is between the protrusion insulating side surface and the connection opening.

The display panel may further include a first base insulating layer between the first resin layer and the second resin layer, and below a portion of the pad electrode.

The display panel may further include a second base insulating layer between the first base insulating layer and the second resin layer, and having a portion above the pad electrode.

The first base insulating layer and the second base insulating layer may include silicon oxide.

The upper resin opening may have a size that is greater than a size of the connection opening in plan view.

The upper resin opening may have a size that is smaller than a size of the main opening in plan view.

The insulating layer may overlap a boundary between the pad conductive portion and the data conductive portion.

A distance from the protrusion barrier side surface to a center of the upper resin opening may be greater than a distance from the main barrier side surface to the center of the upper resin opening.

The barrier layer may include at least one of silicon oxide or silicon nitride.

The barrier opening may be defined by the protrusion barrier side surface, the main barrier side surface, and a sub-barrier side surface connecting the protrusion barrier side surface and the main barrier side surface, wherein the protrusion barrier side surface is substantially parallel to a first direction, and wherein the sub-barrier side surface is substantially parallel to a second direction crossing the first direction.

The pad electrode may be provided in plural, the pad electrodes being spaced apart in a first direction.

The upper resin opening may be provided in plural, portions of upper surfaces of the pad electrodes being exposed through the upper resin openings.

The connection opening may be between the upper resin opening and the display area.

The upper resin opening may be between the connection opening and the display area.

The upper resin opening may include a first upper resin opening and a second upper resin opening spaced apart from the first upper resin opening in a fourth direction crossing a first direction and a second direction that crosses the first direction, wherein the connection opening includes a first connection opening spaced apart from the first upper resin opening in the second direction, and a second connection opening spaced apart from the second upper resin opening in a direction opposite to the second direction.

The connection opening may include a first-first connection opening adjacent to the display area, and a first-second connection opening spaced apart from the first-first connection opening with the upper resin opening therebetween in plan view.

Embodiments of the present disclosure provide an electronic device including a flexible circuit board, and a display panel above the flexible circuit board, and including a display area, a non-display area adjacent to the display area, a base layer including a first resin layer overlapping the display area and the non-display area and defining a lower resin opening, and a second resin layer above the first resin layer and defining an upper resin opening overlapping the non-display area, a pad electrode between the first resin layer and the second resin layer, overlapping the non-display area, having a portion of a lower surface contacting the flexible circuit board through the lower resin opening, and having a portion of an upper surface exposed through the upper resin opening, a driving element layer including a barrier layer above the second resin layer and defining a barrier opening overlapping the upper resin opening, a data line above the barrier layer, a conductive pattern including a pad conductive portion in the upper resin opening and contacting the pad electrode, and a data conductive portion contacting the data line, an insulating layer above the conductive pattern, defining a connection opening exposing a portion of the data conductive portion, and defining a main opening overlapping the upper resin opening, and a bridge conductive pattern above the conductive pattern and the insulating layer, contacting the pad conductive portion through the upper resin opening, and contacting the data conductive portion through the connection opening, and a display element layer including a light-emitting element above the second resin layer, overlapping the display area, and electrically connected to the data line, wherein the barrier opening is defined by a protrusion barrier side surface adjacent to the connection opening, and by a main barrier side surface surrounding a portion of the upper resin opening in plan view, wherein the main opening is defined by a protrusion insulating side surface adjacent to the connection opening, and by a main insulating side surface surrounding a portion of the upper resin opening in plan view and overlapping the main barrier side surface in plan view, and wherein the protrusion insulating side surface is between the protrusion barrier side surface and the upper resin opening.

The display element layer may further include a transistor electrically connected to the light-emitting element and to the data line.

The data line may overlap the display area and the non-display area.

Embodiments of the present disclosure provide a method of manufacturing a display panel, the method including providing a pad electrode on a first resin layer, providing a preliminary second resin layer above the first resin layer, and covering the pad electrode, providing a preliminary barrier layer above the preliminary second resin layer, etching a portion of the preliminary second resin layer to provide a second resin layer defining an upper resin opening to expose a portion of an upper surface of the pad electrode, etching a portion of the preliminary barrier layer to provide a barrier layer defining a barrier opening overlapping the upper resin opening, providing a data line above the barrier layer, providing a conductive pattern including a pad conductive portion in the upper resin opening and contacting the pad electrode, and a data conductive portion contacting the data line, providing a preliminary insulating layer above the conductive pattern, etching a portion of the preliminary insulating layer to provide an insulating layer above the conductive pattern, defining a connection opening exposing a portion of the data conductive portion, and defining a main opening overlapping the upper resin opening, and providing a bridge conductive pattern above the conductive pattern and the insulating layer to contact the pad conductive portion through the upper resin opening, and to contact the data conductive portion through the connection opening, wherein the barrier opening is defined by a protrusion barrier side surface adjacent to the connection opening, and by a main barrier side surface surrounding a portion of the upper resin opening in plan view, wherein the main opening is defined by a protrusion insulating side surface adjacent to the connection opening, and a main insulating side surface surrounding a portion of the upper resin opening and overlapping the main barrier side surface in plan view, and wherein the protrusion barrier side surface is between the protrusion insulating side surface and the connection opening.

According to the display panel, and according to the electronic device including the same, the insulating layer through which the main opening and the connection opening are defined, and the bridge conductive pattern electrically connected to the conductive pattern via the main opening and the connection opening, are located on the conductive pattern, which transmits a signal from the circuit board to the data line, and thus, a size of the non-display area is reduced while improving the reliability of the display panel.

### BRIEF DESCRIPTION OF THE DRAWINGS

The above and other aspects of the present disclosure will become readily apparent by reference to the following detailed description when considered in conjunction with the accompanying drawings wherein:

FIG. 1 is a perspective view of an electronic device according to one or more embodiments of the present disclosure;

FIG. 2 is an exploded perspective view of an electronic device according to one or more embodiments of the present disclosure;

FIG. 3 is a cross-sectional view of a display device taken along the line I-I′ of FIG. 2;

FIG. 4 is a cross-sectional view of a display module according to one or more embodiments of the present disclosure;

FIG. 5 is a plan view of a display panel according to one or more embodiments of the present disclosure;

FIG. 6 is a cross-sectional view of a display module according to one or more embodiments of the present disclosure;

FIG. 7A is a plan view of an input sensor according to one or more embodiments of the present disclosure;

FIG. 7B is a cross-sectional view of an input sensor taken along the line II-II′ of FIG. 7A;

FIG. 8 is an enlarged plan view of a non-display area of a display module according to one or more embodiments of the present disclosure;

FIG. 9 is a cross-sectional view of a display module taken along the line III-III′ of FIG. 8;

FIG. 10 is an enlarged plan view of a non-display area of a display module according to one or more embodiments of the present disclosure;

FIG. 11 is an enlarged plan view of an area AA′ of FIG. 10;

FIG. 12 is a cross-sectional view of a display panel taken along the line IV-IV′ of FIG. 11;

FIG. 13 is an enlarged plan view of an area BB′ of FIG. 12;

FIG. 14 is an enlarged plan view of a non-display area of a display module according to one or more embodiments of the present disclosure;

FIG. 15 is an enlarged plan view of an area CC′ of FIG. 14;

FIG. 16 is a cross-sectional view of a display panel taken along the line V-V′ of FIG. 15;

FIG. 17 is a flowchart illustrating a method of manufacturing a display panel according to one or more embodiments of the present disclosure; and

FIGS. 18 to 25 are views illustrating processes of a method of manufacturing a display device according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

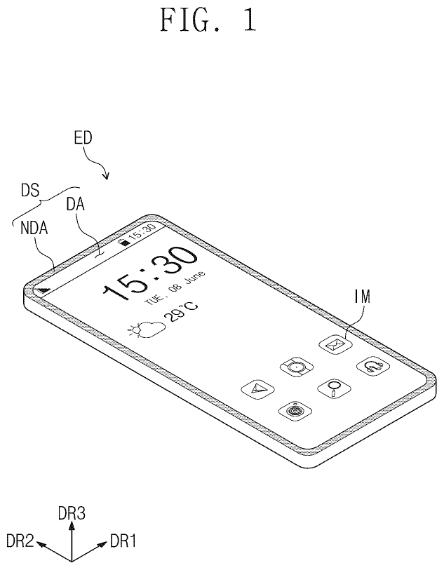

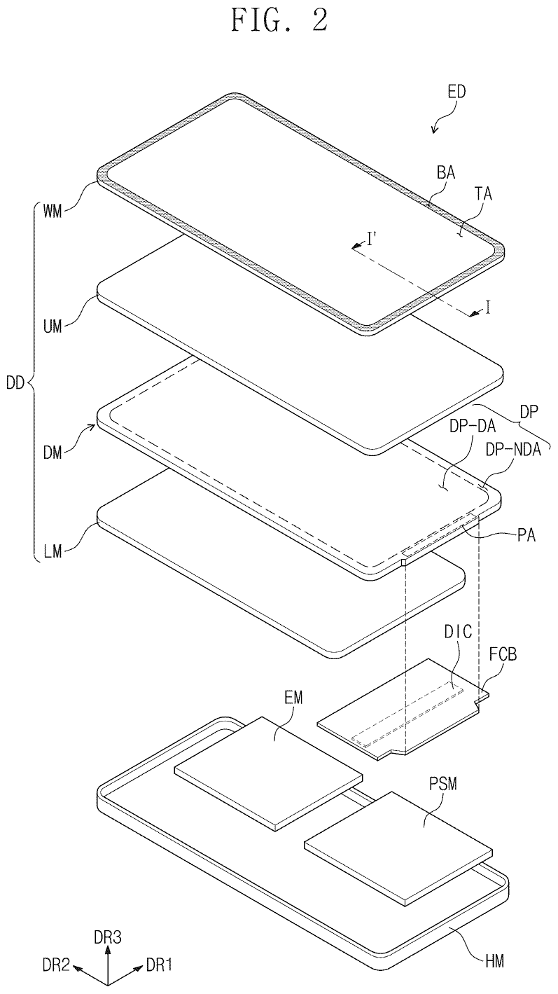

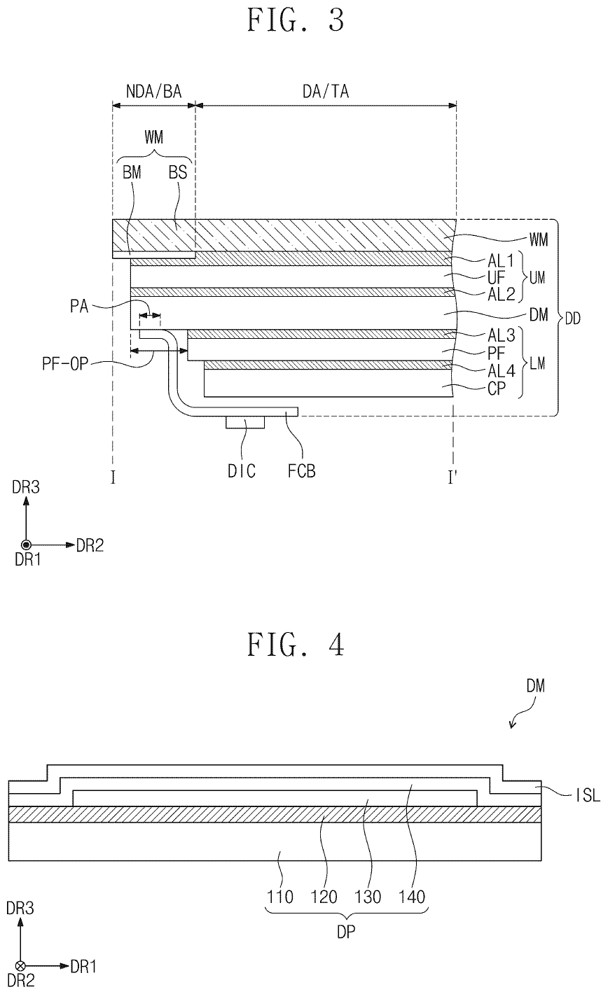

FIG. 1 is a perspective view of an electronic device ED according to one or more embodiments of the present disclosure. FIG. 2 is an exploded perspective view of the electronic device ED according to one or more embodiments of the present disclosure. FIG. 3 is a cross-sectional view of a display device DD taken along the line I-I′ of FIG. 2.

Referring to FIG. 1, the electronic device ED may include a display surface DS defined by a first direction DR1, and a second direction DR2 crossing the first direction DR1. The electronic device ED may provide an image IM to a user through the display surface DS.

The display surface DS may include a display area DA, and a non-display area NDA around the display area DA. The display area DA may display the image IM, and the non-display area NDA may not display, or may be unable to display, an image. The non-display area NDA may surround the display area DA (e.g., in plan view). However, the present disclosure should not be limited thereto or thereby, and the shape of the display area DA and the shape of the non-display area NDA may be changed.

Hereinafter, a direction substantially perpendicular to the plane defined by the first direction DR1 and the second direction DR2 may be referred to as a third direction DR3. Front and rear surfaces of each member of the electronic device ED may be distinguished from each other with respect to the third direction DR3. In the present disclosure, the expression “when viewed in a plane” or “in plan view” may mean a state of being viewed in the third direction DR3.

The electronic device ED may be a foldable electronic device configured to be folded with respect to a folding axis. The folding axis may be substantially parallel to the first direction DR1 or the second direction DR2, and a folding area may be defined in a portion of the display area DA. The electronic device ED may be inwardly folded (inner-folding) to allow a portion of the display area DA to face the other portion of the display area DA, or may be outwardly folded (outer-folding) to allow the portion of the display area DA not to face the other portion of the display area DA.

Referring to FIG. 2, the electronic device ED may include the display device DD, an electronic module EM, a power source module PSM, and a housing HM. The electronic device ED is schematically shown in FIG. 2, and the electronic device ED may further include a mechanical structure (e.g., a hinge) to control an operation, for example, a folding or rolling operation, of the display device DD.

The display device DD may generate the image IM and may sense an external input. The display device DD may include a window WM, an upper member UM, a display module DM, a lower member LM, a flexible circuit board FCB, and a driving chip DIC. The upper member UM may include components located above the display module DM, and the lower member LM may include components located below the display module DM.

The window WM may provide a front surface of the electronic device ED. The window WM may include a transmission area TA and a bezel area BZA. The display area DA and the non-display area NDA of the display surface DS shown in FIG. 1 may be defined by the transmission area TA and the bezel area BZA. The transmission area TA may be an area through which the image passes, and the bezel area BZA may be an area that covers structures/members located under the window WM.

The display module DM may include at least a display panel DP. FIG. 2 shows only the display panel DP among components of the display module DM. However, the display module DM may further include additional components located above the display panel DP in addition to the display panel DP. The stack structure of the display module DM will be described in detail later.

The display panel DP may be an organic light-emitting display panel or an inorganic light-emitting display panel, although it should not be particularly limited. The display panel DP may include a display area DP-DA and a non-display area DP-NDA, which respectively correspond to the display area DA and the non-display area NDA shown in FIG. 1. In the present disclosure, the expression “an area/portion corresponds to another area/portion” may mean that “an area/portion overlaps another area/portion.” However, they should not be limited to having the same size as each other.

A pad area PA may be defined at one side of the non-display area DP-NDA. The pad area PA may be electrically bonded or connected to the flexible circuit board FCB described later. The pad area PA may be defined in a rear surface of the display panel DP.

The display panel DP may have a substantially quadrangular shape. The expression “a substantially quadrangular shape” used herein may mean not only the mathematical concept of a rectangular shape, but also shapes that are similar to rectangles and perceived by the user as rectangles. For instance, the substantially quadrangular shape may include a quadrangular shape with a rounded corner. In addition, an edge of a display panel DP having the substantially rectangular shape should not be limited to a straight line, and the edge may have a curved area.

The upper member UM may include a protective film or an optical film. The optical film may include a polarizer or a retarder to reduce a reflection of an external light. The lower member LM may include a protective film protecting the display panel DP, a support member supporting the display panel DP, and a digitizer. The upper member UM and the lower member LM will be described in detail later.

The flexible circuit board FCB shown in FIG. 2 may be located under the display panel DP. The flexible circuit board FCB may be bonded to a rear surface of the display panel DP, and may electrically connect the display panel DP to a main circuit board. The flexible circuit board FCB may include at least one insulating layer and at least one conductive layer. The conductive layer may include a plurality of signal lines.

The driving chip DIC may be mounted on the flexible circuit board FCB. The driving chip DIC may include a driving circuit (e.g., a data-driving circuit) to drive pixels of the display panel DP. FIG. 2 shows a structure in which the driving chip DIC is mounted on the flexible circuit board FCB, however, the present disclosure should not be limited thereto or thereby. As an example, the driving chip DIC may be mounted on the display panel DP or the main circuit board.

The electronic module EM may include a control module, a wireless communication module, an image input module, an audio input module, an audio output module, a memory, and an external interface module. The electronic module EM may include the main circuit board, and the modules may be mounted on the main circuit board or may be electrically connected to the main circuit board via a flexible circuit board. The electronic module EM may be electrically connected to the power source module PSM.

In one or more embodiments, the electronic device ED may further include an electro-optical module. The electro-optical module may be an electronic component that outputs or receives an optical signal. The electro-optical module may include a camera module and/or a proximity sensor. The camera module may take a picture of an external object via an area of the display panel DP.

The housing HM shown in FIG. 2 may be coupled to the display device DD, for example, to the window WM to accommodate the above-mentioned modules. The housing HM is shown as having an integral shape, although it should not be limited thereto or thereby. The housing HM may include a plurality of portions, for instance, a side surface edge portion and a bottom portion, coupled to each other.

FIG. 3 further shows adhesive layers AL1, AL2, AL3, and AL4 that are not shown in FIG. 2. The window WM may include a base substrate BS and a bezel pattern BM located on a lower surface of the base substrate BS. The base substrate BS may include a synthetic resin film or a glass substrate. The base substrate BS may have a multi-layer structure. The base substrate BS may include a thin glass substrate, a protective film located on the thin glass substrate, and an adhesive layer that attaches the thin glass substrate and the protective film.

The bezel pattern BM may be a colored light-blocking layer and may be formed by a coating process. The bezel pattern BM may include a base material and a pigment or dye mixed with the base material. The bezel pattern BM may overlap the non-display area NDA shown in FIG. 1 and the bezel area BZA shown in FIG. 2. The bezel pattern BM may be located on the lower surface of the base substrate BS. When the base substrate BS has a multi-layer structure, the bezel pattern BM may be located at an interface defined between plural layers. For instance, the bezel pattern BM may be located between the thin glass substrate and the protective film. In one or more embodiments, the window WM may include at least one of a hard coating layer, an anti-fingerprint layer, or an anti-reflective layer located on an upper surface of the base substrate BS.

The upper member UM may include an upper film UF. The upper film UF may include a synthetic resin film. The synthetic resin film may include polyimide, polycarbonate, polyamide, triacetylcellulose, polymethylmethacrylate, or polyethylene terephthalate.

The upper film UF may absorb an external impact applied to a front surface of the display device DD. According to one or more embodiments, the display module DM may include a color filter as an anti-reflective member to replace a polarizing film, and in this case, an impact resistance of the display device DD with respect to external impacts applied to the front surface thereof may be reduced. The upper film UF may compensate for the reduction of the impact resistance with respect to the external impacts, which is caused by applying the color filter to the display module DM.

The upper film UF may overlap the bezel area BZA and the transmission area TA. The upper film UF may overlap only a portion of the bezel area BZA. A portion of the bezel pattern BM may be exposed without being covered by the upper film UF. According to one or more embodiments, the upper film UF may be omitted. According to one or more embodiments, the upper film UF may be replaced with the optical film including the polarizer and the retarder.

The upper member UM may further include a first adhesive layer AL1 used to attach the upper film UF to the window WM, and a second adhesive layer AL2 used to attach the upper film UF to the display module DM. The first adhesive layer AL1 and the second adhesive layer AL2 may be a pressure sensitive adhesive (PSA) film or an optically clear adhesive (OCA). Adhesive layers described hereinafter may also include the same adhesive as the first adhesive layer AL1.

The display module DM may be located under the upper film UF. The display module DM may overlap the bezel area BZA and the transmission area TA. The display module DM may completely overlap the upper film UF in the bezel area BZA. A side surface of the display module DM may be aligned with a side surface of the upper film UF, and a corner of the display module DM may be aligned with a corner of the upper film UF when viewed in the plane.

In the bezel area BZA, the pad area PA of the display module DM may overlap the upper film UF. A portion of the display module DM, which corresponds to the pad area PA, may be coupled with a lower surface of the upper film UF by the second adhesive layer AL2. As the pad area PA overlaps the upper film UF and the portion of the display module DM overlapping the pad area PA is coupled with the upper film UF, the upper film UF may sufficiently support the pad area PA when the circuit board FCB is bonded to the pad area PA.

The lower member LM may include a lower film PF, a cover panel CP, a third adhesive layer AL3, and a fourth adhesive layer AL4. The lower member LM may further include a support plate and a digitizer.

The lower film PF may be located under the display module DM, and may be coupled to the lower surface of the display module DM by the third adhesive layer AL3. The lower film PF may protect a lower portion of the display module DM. The lower film PF may include a flexible synthetic resin film. As an example, the lower film PF may include polyethylene terephthalate or polyimide. However, the present disclosure should not be limited thereto or thereby.

The lower film PF may expose at least the pad area PA of the display module DM. The lower film PF may have an area that is smaller than that of the display module DM. For instance, the lower film PF may overlap only the display area DA.

The lower film PF may have substantially the same size as the display module DM. The lower film PF may be provided with an opening area PF-OP defined therein to correspond to the pad area PA (refer to FIG. 2). Even though the lower film PF entirely protects the lower surface of the display module DM, the open area PF-OP may be defined to allow the flexible circuit board FCB to approach the pad area PA.

As shown in FIG. 3, the lower film PF may be coupled with the cover panel CP by the fourth adhesive layer AL4. The cover panel CP may increase a resistance against a compressive force caused by external pressure force. Accordingly, the cover panel CP may reduce or prevent deformation of the display module DM. The cover panel CP may include a flexible plastic material, such as polyimide or polyethylene terephthalate. In addition, the cover panel CP may be a colored film with low light transmittance. The cover panel CP may absorb a light incident thereto from the outside. As an example, the cover panel CP may be a black synthetic resin film. When looking at the display device DD from an upper side of the window WM, components located under the cover panel CP may not be viewed by the user.

In one or more embodiments, the support plate may be further located under the cover panel CP. The support plate may include a high-strength metal material. The support plate may include a reinforced fiber composite material. The support plate may include a reinforced fiber located in a matrix portion. The reinforced fiber may be a carbon fiber or a glass fiber. The matrix portion may include a polymer resin. The matrix portion may include a thermoplastic resin. As an example, the matrix portion may include a polyamide-based resin or a polypropylene-based resin. For example, the reinforced fiber composite material may be a carbon fiber reinforced plastic (CFRP) or a glass fiber reinforced plastic (GFRP).

FIG. 4 is a cross-sectional view of the display module DM according to one or more embodiments of the present disclosure.

Referring to FIG. 4, the display module DM may include the display panel DP and an input sensor ISL. The display panel DP may include a base layer 110, a driving element layer 120, and a light-emitting element layer 130. The display panel DP may further include an encapsulation layer 140.

The base layer 110 may be a flexible substrate that is bendable, foldable, or rollable. The base layer 110 may be a glass substrate, a metal substrate, or a polymer substrate. However, the present disclosure should not be limited thereto or thereby. According to one or more embodiments, the base layer 110 may be an inorganic layer, an organic layer, or a composite material layer. The base layer 110 may have substantially the same shape as the display panel DP.

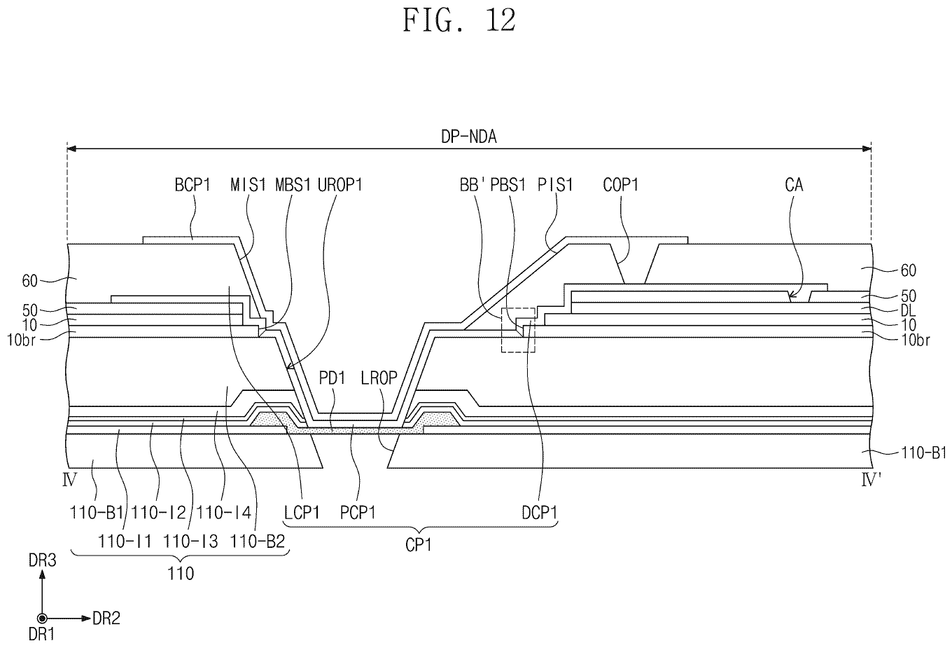

The base layer 110 may include a first resin layer (refer to 110-B1 of FIG. 12), a second resin layer (refer to 110-B2 of FIG. 12). Each of the first and second resin layers may include a polyimide-based resin. However, embodiments of the present disclosure are not limited thereby. The structure of the base layer 110 will be described in detail with reference to FIG. 12.

The driving element layer 120 may be located on the base layer 110 (as used herein, “located on” may mean “above”). The driving element layer 120 may include a plurality of insulating layers, a plurality of semiconductor patterns, a plurality of conductive patterns, and a plurality of signal lines. The driving element layer 120 may include a pixel-driving circuit. Hereinafter, unless otherwise specified, the expression “components A and B are located on the same layer” may mean that components A and B are formed through the same process and contain the same material or have the same stack structure. The conductive patterns or semiconductor patterns located on the same layer may be interpreted as described above.

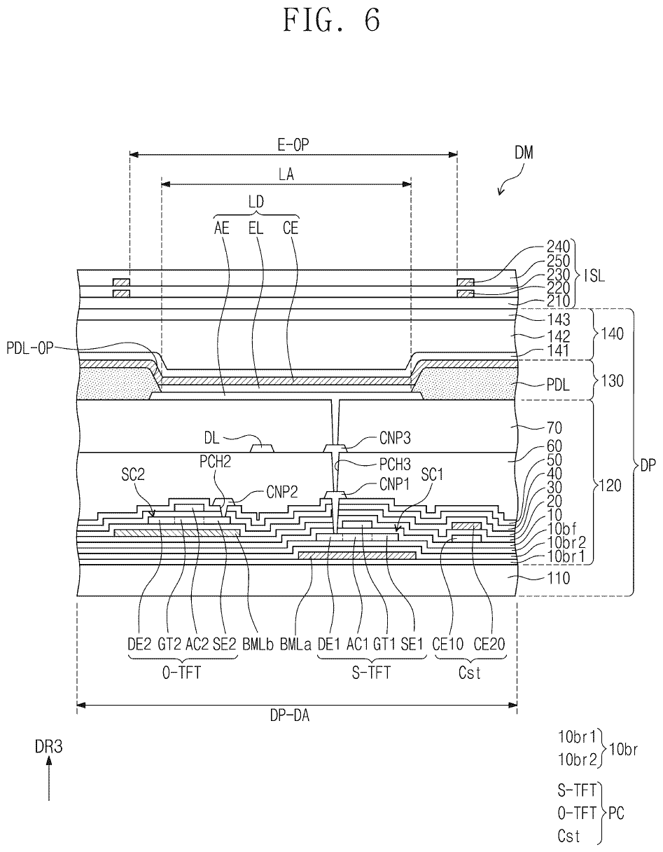

The light-emitting element layer 130 may be located on the driving element layer 120. The light-emitting element layer 130 may include a light-emitting element and a transistor. For example, the light-emitting element may include an organic light-emitting material, an inorganic light-emitting material, an organic-inorganic light-emitting material, a quantum dot, a quantum rod, a micro-LED, or a nano-LED. The transistor will be described in detail with reference to FIG. 6.

The encapsulation layer 140 may be located on the light-emitting element layer 130. The encapsulation layer 140 may protect the light-emitting element layer 130 (e.g., the light-emitting element) from moisture, oxygen, and a foreign substance such as dust particles. The encapsulation layer 140 may include at least one encapsulation inorganic layer. The encapsulation layer 140 may include a stack structure in which a first encapsulation inorganic layer, an encapsulation organic layer, and a second encapsulation inorganic layer are sequentially stacked.

The input sensor ISL may be located directly on the display panel DP. The input sensor ISL may sense a user's input by an electromagnetic induction method or a capacitive method. The display panel DP and the input sensor ISL may be formed through successive processes. The expression “being directly located on” as used herein may mean that no intervening elements are located between the input sensor ISL and the display panel DP. That is, a separate adhesive layer may not be located between the input sensor ISL and the display panel DP.

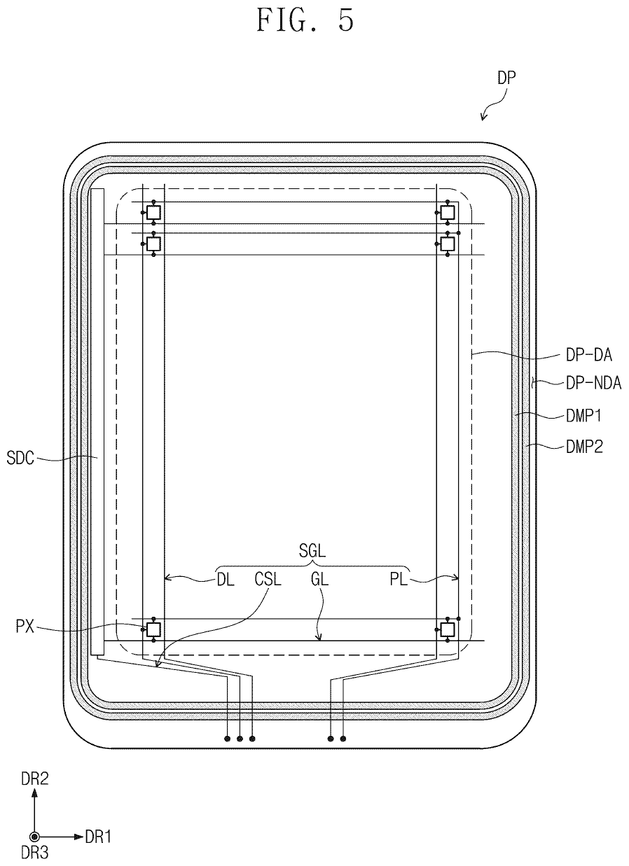

FIG. 5 is a plan view of the display panel DP according to one or more embodiments of the present disclosure. FIG. 6 is a cross-sectional view of the display module DM according to one or more embodiments of the present disclosure.

Referring to FIG. 5, the display panel DP may include a scan-driving circuit SDC, a plurality of signal lines SGL, and a plurality of pixels PX. The pixels PX may be arranged in the display area DP-DA. Each of the pixels PX may include the light-emitting element and the pixel-driving circuit connected to the light-emitting element. The scan-driving circuit SDC, the signal lines SGL, and the pixel-driving circuit may be included in the circuit layer 120 shown in FIG. 4.

The scan-driving circuit SDC may include a gate-driving circuit. The gate-driving circuit may generate a plurality of scan signals and may sequentially output the scan signals to a plurality of scan lines GL described later. The scan-driving circuit SDC may further include a light emission-driving circuit distinguished from the gate-driving circuit. The light emission-driving circuit may further output scan signals to another group of scan lines.

The scan-driving circuit SDC may include a plurality of thin film transistors formed through the same processes (e.g., a low temperature polycrystalline silicon (LTPS) process or a low temperature polycrystalline oxide (LTPO) process) as the pixel-driving circuit.

The signal lines SGL may include the scan lines GL, data lines DL, a power line PL, and a control signal line CSL. Each of the scan lines GL may be connected to a corresponding pixel PX among the pixels PX, and each of the data lines DL may be connected to a corresponding pixel PX among the pixels PX. The power line PL may be connected to the pixels PX. The data lines DL may provide data signals to the pixels PX. The control signal line CSL may provide control signals to the scan-driving circuit SDC.

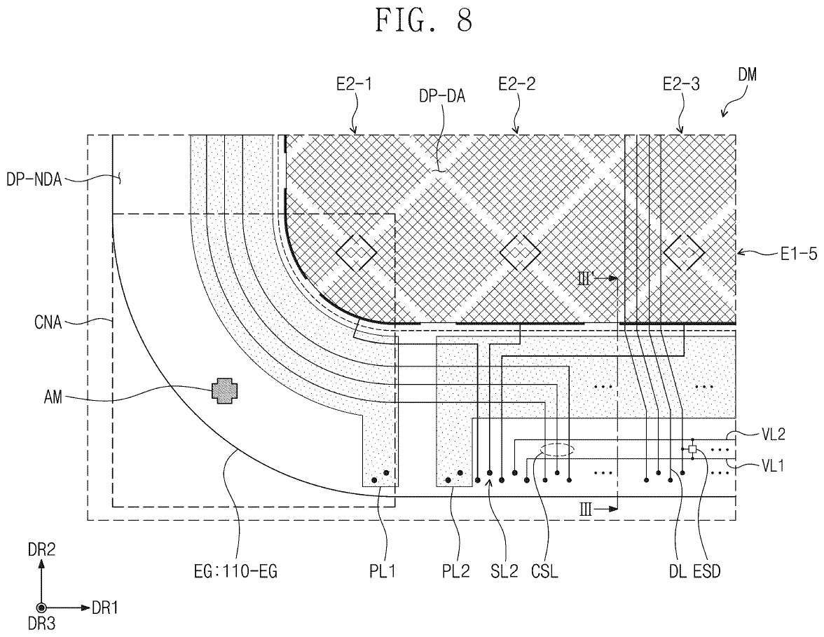

As shown in FIG. 8, the power line PL may include a first power line PL1 for receiving a first power supply voltage, and a second power line PL2 for receiving a second power supply voltage having a level higher than the first power supply voltage. The first power supply voltage may be provided to the pixel PX via the first power line PL1, and the second power supply voltage may be provided to the pixel PX via the second power line PL2. One control signal line CSL is shown in FIG. 5 as a representative example, although the control signal line CSL may be provided in plural.

The scan lines GL, the data lines DL, and the power line PL may overlap the display area DP-DA and the non-display area DP-NDA, and the control signal line CSL may overlap the non-display area DP-NDA. Each of the signal lines SGL may have an integral shape, but may include a plurality of portions located on different layers. The different portions distinguished from each other by an insulating layer may be connected to each other via a contact hole defined through the insulating layer. For instance, the data lines DL may include a first portion located in the display area DP-DA, and a second portion located in the non-display area DP-NDA at a different layer from the first portion. The first portion and the second portion may include different materials from each other and may have different stack structures from each other.

The display panel DP may include insulating patterns DMP1 and DMP2. FIG. 5 shows first and second insulating patterns DMP1 and DMP2 as a representative example. The first and second insulating patterns DMP1 and DMP2 may be arranged in the non-display area DP-NDA, and may surround the display area DP-DA. Each of the first and second insulating patterns DMP1 and DMP2 may have a closed line shape. The first and second insulating patterns DMP1 and DMP2 may act as a dam to reduce or prevent the likelihood of a liquid organic material overflowing in an inkjet process for the display panel DP.

FIG. 6 is a cross-sectional view of the display module DM corresponding to the pixel PX of FIG. 5.

The pixel-driving circuit PC that drives the light-emitting element LD may include a plurality of pixel-driving elements. The pixel-driving circuit PC may include a plurality of transistors S-TFT and O-TFT and a capacitor Cst. FIG. 6 shows a silicon transistor S-TFT and an oxide transistor O-TFT as a representative example of the transistors. The pixel-driving circuit PC of FIG. 6 is merely an example, and components of the pixel-driving circuit PC should not be limited thereto or thereby. The pixel-driving circuit PC may include only one type of transistor between the silicon transistor S-TFT and the oxide transistor O-TFT.

Referring to FIG. 6, the base layer 110 may include the first resin layer (refer to 110-B1 of FIG. 12) and the second resin layer (refer to 110-B2 of FIG. 12), even though the base layer 110 is shown as having a single-layer structure. The base layer 110 may include a synthetic resin such as polyimide. The base layer 110 may be formed by coating a synthetic resin layer on a work substrate (or a carrier substrate). When the display module DM is completed through subsequent processes, the work substrate may be removed.

Referring to FIG. 6, a barrier layer 10br may be located on (e.g., above) the base layer 110. The barrier layer 10br may reduce or prevent the likelihood of a foreign substance entering thereinto from the outside. The barrier layer 10br may include at least one inorganic layer. The barrier layer 10br may include a silicon oxide layer and a silicon nitride layer. Each of the silicon oxide layer and the silicon nitride layer may be provided in plural, and the silicon oxide layers may be alternately stacked with the silicon nitride layers.

The barrier layer 10br may include a lower barrier layer 10br1 and an upper barrier layer 10br2. A first shielding electrode BMLa may be located between the lower barrier layer 10br1 and the upper barrier layer 10br2. The first shielding electrode BMLa may correspond to the silicon transistor S-TFT. The first shielding electrode BMLa may include a metal material (e.g., molybdenum).

The first shielding electrode BMLa may receive a bias voltage. The first shielding electrode BMLa may receive the first power supply voltage. The first shielding electrode BMLa may reduce or prevent the likelihood of an electric potential, which is caused by a polarization phenomenon, exerting influence on the silicon transistor S-TFT. The first shielding electrode BMLa may reduce or prevent external light reaching the silicon transistor S-TFT. According to one or more embodiments, the first shielding electrode BMLa may be a floating electrode isolated from other electrodes or lines.

A buffer layer 10bf may be located on the barrier layer 10br. The buffer layer 10bf may reduce or prevent metal atoms or impurities being diffused to a first semiconductor pattern SC1 located thereon from the base layer 110. The buffer layer 10bf may include at least one inorganic layer. The buffer layer 10bf may include a silicon oxide layer and a silicon nitride layer.

The first semiconductor pattern SC1 may be located on the buffer layer 10bf. The first semiconductor pattern SC1 may include a silicon semiconductor. As an example, the silicon semiconductor may include amorphous silicon or polycrystalline silicon. For example, the first semiconductor pattern SC1 may include low temperature polycrystalline silicon.

The first semiconductor pattern SC1 may have different electrical properties depending on whether it is doped or not. The first semiconductor pattern SC1 may include a first region having a relatively high conductivity, and a second region having a relatively low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or a region doped at a concentration lower than that of the first region. The first semiconductor pattern SC1 may be the N-type transistor.

The first region may have a conductivity that is greater than that of the second region, and may substantially serve as an electrode or signal line. The second region may substantially correspond to a channel area (or an active area) of a transistor. In other words, a portion of the first semiconductor pattern SC1 may be a channel of the transistor, another portion of the first semiconductor pattern SC1 may be a source or a drain of the transistor, and the other portion of the first semiconductor pattern SC1 may be a connection electrode or a connection signal line.

A source area SE1, a channel area AC1 (or an active area), and a drain area DE1 of the silicon transistor S-TFT may be formed from the first semiconductor pattern SC1. The source area SE1 and the drain area DE1 may extend in opposite directions to each other from the channel area AC1.

A first insulating layer 10 may be located on the buffer layer 10bf. The first insulating layer 10 may cover the first semiconductor pattern SC1. The first insulating layer 10 may be an inorganic layer. The first insulating layer 10 may have a single-layer structure of a silicon oxide layer. However, the present disclosure should not be limited thereto or thereby. An inorganic layer of the driving element layer 120 described later may have a single-layer or multi-layer structure and may include at least one of the above-mentioned materials. However, the present disclosure should not be limited thereto or thereby.

A gate GT1 of the silicon transistor S-TFT may be located on the first insulating layer 10. The gate GT1 may be a portion of a metal pattern. The gate GT1 may overlap the channel area AC1. The gate GT1 may be used as a mask in a process of doping the first semiconductor pattern SC1. A first electrode CE10 of the capacitor Cst may be located on the first insulating layer 10. Different from those shown in FIG. 6, the gate GT1 and the first electrode CE10 may be provided integrally with each other.

A second insulating layer 20 may be located on the first insulating layer 10 and may cover the gate GT1. An upper electrode may be further located on the second insulating layer 20 to overlap the gate GT1. A second electrode CE20 may be located on the second insulating layer 20 to overlap the first electrode CE10. The upper electrode may be provided integrally with the second electrode CE20 when viewed in a plane.

A second shielding electrode BMLb may be located on the second insulating layer 20. The second shielding electrode BMLb may correspond to the oxide transistor O-TFT. According to one or more embodiments, the second shielding electrode BMLb may be omitted. According to one or more embodiments, the first shielding electrode BMLa may extend to a lower portion of the oxide transistor O-TFT, and may replace the second shielding electrode BMLb.

A third insulating layer 30 may be located on the second insulating layer 20. A second semiconductor pattern SC2 may be located on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include a transparent conductive oxide (TCO), such as indium tin oxide (ITO), indium zinc oxide (IZO), indium gallium zinc oxide (IGZO), zinc oxide (ZnOx), or indium oxide (In₂O₃).

The metal oxide semiconductor may include a plurality of areas SE2, AC2, and DE2 distinguished from each other depending on whether a transparent conductive oxide is reduced or not. The area (hereinafter, referred to as a reduced area) in which the transparent conductive oxide is reduced has a conductivity that is greater than that of the area (hereinafter, referred to as a non-reduced area) in which the transparent conductive oxide is not reduced. The reduced area may substantially act as a source/drain of a transistor or a signal line. The non-reduced area may substantially correspond to a semiconductor area (or a channel) of the transistor. In other words, a portion of the second semiconductor pattern SC2 may be the semiconductor area of the transistor, another portion of the second semiconductor pattern SC2 may be a source area SE2/a drain area DE2 of the transistor, and the other portion of the second semiconductor pattern SC2 may be a signal transmission area.

A fourth insulating layer 40 may be located on the third insulating layer 30. As shown in FIG. 6, the fourth insulating layer 40 may cover the second semiconductor pattern SC2. According to one or more embodiments, the fourth insulating layer 40 may be an insulating pattern that overlaps a gate GT2 of the oxide transistor O-TFT, and that exposes the source area SE2 and the drain area DE2.

The gate GT2 of the oxide transistor O-TFT may be located on the fourth insulating layer 40. The gate GT2 of the oxide transistor O-TFT may be a portion of a metal pattern. The gate GT2 of the oxide transistor O-TFT may overlap the channel area AC2.

A fifth insulating layer 50 may be located on the fourth insulating layer 40 and may cover the gate GT2. Each of the first to fifth insulating layers 10, 20, 30, 40, and 50 may be an inorganic layer.

A first connection pattern CNP1 and a second connection pattern CNP2 may be located on the fifth insulating layer 50. The first connection pattern CNP1 and the second connection pattern CNP2 may be formed through the same process, and thus, the first connection pattern CNP1 and the second connection pattern CNP2 may include the same material and the same stack structure. The first connection pattern CNP1 may be connected to the drain area DE1 of the silicon transistor S-TFT via a first pixel contact hole PCH1 defined through the first, second, third, fourth, and fifth insulating layers 10, 20, 30, 40, and 50. The second connection pattern CNP2 may be connected to the source area SE2 of the oxide transistor O-TFT via a second pixel contact hole PCH2 defined through the fourth and fifth insulating layers 40 and 50. The connection relationship of the first connection pattern CNP1 and the second connection pattern CNP2 with respect to the silicon transistor S-TFT and the oxide transistor O-TFT should not be limited thereto or thereby.

A sixth insulating layer 60 may be located on the fifth insulating layer 50. A third connection pattern CNP3 may be located on the sixth insulating layer 60. The third connection pattern CNP3 may be connected to the first connection pattern CNP1 via a third pixel contact hole PCH3 defined through the sixth insulating layer 60. The data line DL may be located on the sixth insulating layer 60. An upper insulating layer 70 may be located on the sixth insulating layer 60, and may cover the third connection pattern CNP3 and the data line DL. The third connection pattern CNP3 and the data line DL may be formed through the same process, and thus, the third connection pattern CNP3 and the data line DL may include the same material and the same stack structure. Each of the sixth insulating layer 60 and the upper insulating layer 70 may be an organic layer.

The first shielding electrode BMLa, the gate GT1 of the silicon transistor S-TFT, the second electrode CE20, and the gate GT2 of the oxide transistor O-TFT may include molybdenum (Mo), an alloy including molybdenum (Mo), titanium (Ti), or an alloy including titanium (Ti), which has good heat resistance. The first connection pattern CNP1 and the second connection pattern CNP2 may include aluminum with high electrical conductivity. The first connection pattern CNP1 and the second connection pattern CNP2 may have a three-layer structure of titanium/aluminum/titanium.

The light-emitting element LD may include an anode (or a first electrode) AE, a light-emitting layer EL, and a cathode (or a second electrode) CE. The anode AE of the light-emitting element LD may be located on the upper insulating layer 70. The anode AE may be a transmissive electrode, a semi-transmissive electrode, or a reflective electrode. The anode AE may have a stack structure of ITO/Ag/ITO sequentially stacked. Positions of the anode AE and the cathode CE may be interchanged.

A pixel definition layer PDL may be located on the upper insulating layer 70. The pixel definition layer PDL may be an organic layer. The pixel definition layer PDL may have a light-absorbing property and may have a black color. As an example, the pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light-blocking pattern having a light-blocking property.

The pixel definition layer PDL may cover a portion of the anode AE. As an example, an opening PDL-OP may be defined through the pixel definition layer PDL to expose a portion of the anode AE. A light-emitting area LA may be defined to correspond to the opening PDL-OP. In the present disclosure, a hole control layer may be located between the anode AE and the light-emitting layer EL. The hole control layer may include a hole transport layer, and may further include a hole injection layer. An electron control layer may be located between the light-emitting layer EL and the cathode CE. The electron control layer may include an electron transport layer, and may further include an electron injection layer.

The encapsulation layer 140 may cover the light-emitting element LD. The encapsulation layer 140 may include an encapsulation inorganic layer 141, an encapsulation organic layer 142, and an encapsulation inorganic layer 143, which are sequentially stacked, however, layers forming the encapsulation layer 140 should not be limited thereto or thereby. The encapsulation inorganic layers 141 and 143 may include a silicon nitride layer, a silicon oxynitride layer, a silicon oxide layer, a titanium oxide layer, or an aluminum oxide layer. Each of the encapsulation inorganic layers 141 and 143 may have a multi-layer structure. The encapsulation organic layer 142 may include an acryl-based organic layer, but it should not be limited thereto or thereby.

The input sensor ISL may include at least one conductive layer (or at least one sensor conductive layer), and at least one insulating layer (or at least one sensor insulation layer). The input sensor ISL may include a first insulating layer 210 (or a first sensor insulating layer), a first conductive layer 220, a second insulating layer 230 (or a second sensor insulating layer), a second conductive layer 240, and a third insulating layer 250 (or a third sensor insulating layer). FIG. 6 schematically shows a conductive line of the first conductive layer 220 and a conductive line of the second conductive layer 240.

The first insulating layer 210 may be located directly on the display panel DP. The first insulating layer 210 may be an inorganic layer including at least one of silicon nitride, silicon oxynitride, or silicon oxide. Each of the first conductive layer 220 and the second conductive layer 240 may have a single-layer structure or a multi-layer structure of layers stacked in the third direction DR3. The first conductive layer 220 and the second conductive layer 240 may include conductive lines that define an electrode of a mesh shape. The conductive line of the first conductive layer 220 and the conductive line of the second conductive layer 240 may be connected to each other via a contact hole defined through the second insulating layer 230 or may not be connected to each other. The connection relationship between the conductive line of the first conductive layer 220 and the conductive line of the second conductive layer 240 may be determined according to the type of sensor forming the input sensor ISL.

The first conductive layer 220 and the second conductive layer 240, which have the single-layer structure, may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnOx), indium zinc tin oxide (ITZO), or the like. In addition, the transparent conductive layer may include conductive polymer such as PEDOT, metal nanowire, graphene, or the like.

The first conductive layer 220 and the second conductive layer 240, which have the multi-layer structure, may include metal layers. The metal layers may have a three-layer structure of titanium/aluminum/titanium. The first conductive layer 220 and the second conductive layer 240, which have the multi-layer structure, may include at least one metal layer and at least one transparent conductive layer. The second insulating layer 230 may be located between the first conductive layer 220 and the second conductive layer 240. The third insulating layer 250 may cover the second conductive layer 240. According to one or more embodiments, the third insulating layer 250 may be omitted. The second insulating layer 230 and the third insulating layer 250 may include an inorganic layer or an organic layer.

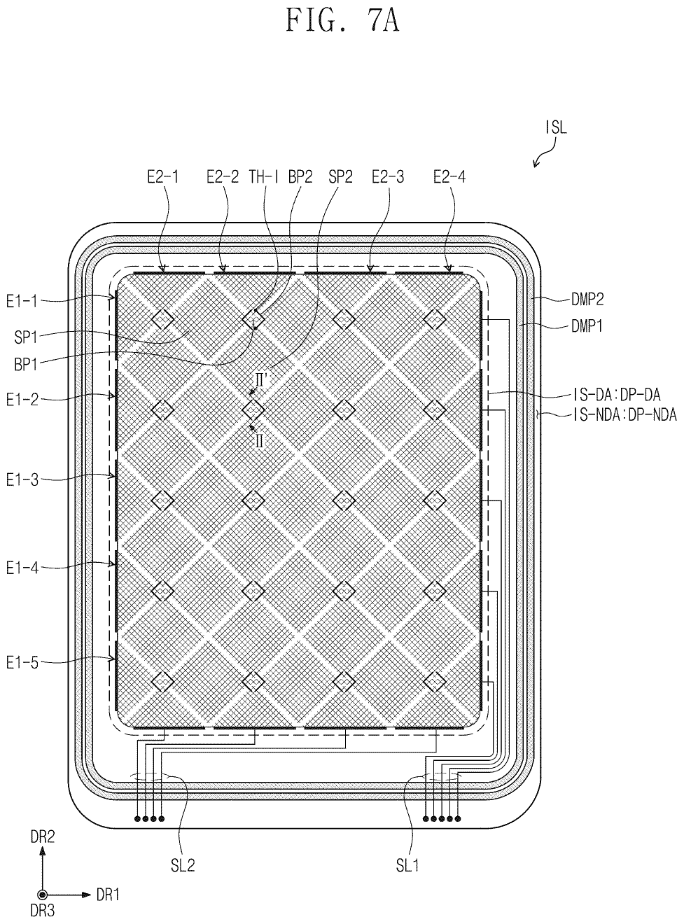

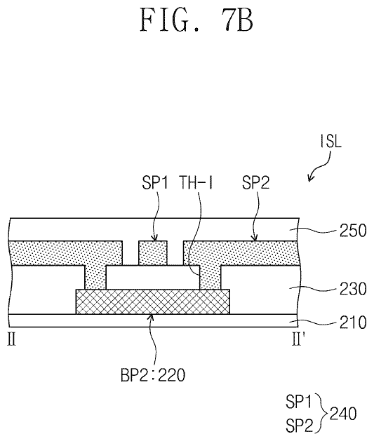

FIG. 7A is a plan view of the input sensor ISL according to one or more embodiments of the present disclosure. FIG. 7B is a cross-sectional view of the input sensor ISL taken along the line II-II′ of FIG. 7A.

Referring to FIG. 7A, the input sensor ISL may include a sensing area IS-DA, and a non-sensing area IS-NDA adjacent to the sensing area IS-DA. The sensing area IS-DA and the non-sensing area IS-NDA may correspond to the display area DP-DA and the non-display area DP-NDA shown in FIG. 5, respectively. The input sensor ISL may include first electrodes (or first sensing electrodes) E1-1 to E1-5, second electrodes (or second sensing electrodes) E2-1 to E2-4, first signal lines (or first sensor signal lines) SL1, and second signal lines (or second sensor signal lines) SL2. The first and second insulating patterns DMP1 and DMP2 are additionally illustrated in FIG. 7A to show relative positions of the first and second insulating patterns DMP1 and DMP2 with respect to the input sensor ISL.

The first electrodes E1-1 to E1-5 and the second electrodes E2-1 to E2-4 insulated from the first electrodes E1-1 to E1-5 while crossing the first electrodes E1-1 to E1-5 may be arranged in the sensing area IS-DA. The first signal lines SL1 electrically connected to the first electrodes E1-1 to E1-5 and the second signal lines SL2 electrically connected to the second electrodes E2-1 to E2-4 may be arranged in the non-sensing area IS-NDA. One of the first signal lines SL1 and the second signal lines SL2 may transmit a driving signal to corresponding electrodes to sense the external input from an external circuit, and the other of the first signal lines SL1 and the second signal lines SL2 may output a sensing signal. A change in capacitance between the first electrodes E1-1 to E1-5 and the second electrodes E2-1 to E2-4 may be measured based on the sensing signal. A mutual capacitance-type input sensor is shown as a representative example, but it should not be limited thereto or thereby. A self-capacitance type input sensor may be used as the input sensor. The self-capacitance type input sensor may include one type of sensing electrodes.

Each of the first electrodes E1-1 to E1-5 and the second electrodes E2-1 to E2-4 may have a mesh shape provided with a plurality of openings defined therethrough. The openings may be defined to correspond to the light-emitting area LA (refer to FIG. 6) of the display panel DP. FIG. 6 shows an opening E-OP corresponding to the light-emitting area. The second electrodes E2-1 to E2-4 may be insulated from the first electrodes E1-1 to E1-5 while crossing the first electrodes E1-1 to E1-5. One of the first electrodes E1-1 to E1-5 and the second electrodes E2-1 to E2-4 may have an integral shape. The first electrodes E1-1 to E1-5 may have an integral shape. The first electrodes E1-1 to E1-5 may include sensing portions SP1 and intermediate portions BP1.

Each of the second electrodes E2-1 to E2-4 may include sensing patterns SP2 and bridge patterns (or connection patterns) BP2. Two sensing patterns SP2 adjacent to each other may be connected to two bridge patterns BP2, however, the number of the bridge patterns should not be particularly limited.

Referring to FIGS. 6 to 7B, the bridge patterns BP2 may be formed from the first conductive layer 220, and the first electrodes E1-1 to E1-5 and the sensing patterns SP2 may be formed from the second conductive layer 240. The bridge pattern BP2 may be connected to the sensing patterns SP2 via a contact hole TH-I formed through the second insulating layer 230.

Each of the first signal lines SL1 and the second signal lines SL2 of FIG. 7A may be formed from the first conductive layer 220 of FIG. 6. Accordingly, each of the first signal lines SL1 and the second signal lines SL2 of FIG. 7A may be located on the same layer as the bridge pattern BP2 of FIG. 7B. However, according to one or more embodiments, each of the first signal lines SL1 and the second signal lines SL2 may be formed from the second conductive layer 240. Each of the first signal lines SL1 and the second signal lines SL2 may include a line formed from the first conductive layer 220 and a line formed from the second conductive layer 240.

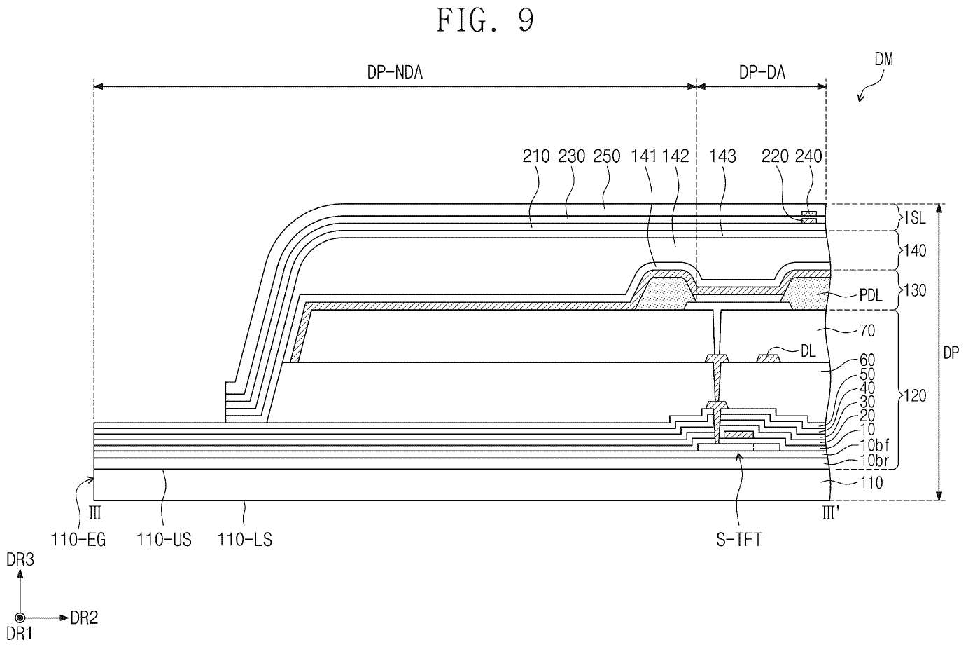

FIG. 8 is an enlarged plan view of the non-display area DP-NDA of the display module DM according to one or more embodiments of the present disclosure. FIG. 9 is a cross-sectional view of the display module DM taken along the line III-III′ of FIG. 8.

Referring to FIGS. 8 and 9, the display area DP-DA and the non-display area DP-NDA of the display module DM are assigned the same reference numerals as the display area DP-DA and the non-display area DP-NDA of the display panel DP of FIG. 5. In addition, the display area DP-DA and the non-display area DP-NDA may respectively correspond to the sensing area IS-DA and the non-sensing area IS-NDA of FIG. 7A. In FIG. 8, the first electrode E1-5 among the first electrodes E1-1 to E1-5 shown in FIG. 7A and some second electrodes E2-1 to E2-3 among the second electrodes E2-1 to E2-4 shown in FIG. 7A are shown in the display area DP-DA, and components of the display panel DP in the display area DP-DA are not illustrated.

FIG. 8 is an enlarged plan view showing one corner area (or a vertex area) CNA and a portion of the non-display area DP-NDA located at a lower side of the display area DP-DA when viewed in the plane based on FIGS. 5 and 7A. Components overlapping each other among the components shown in FIG. 8 are located on different layers from each other.

The first power line PL1 and the second power line PL2 may be arranged in the non-display area DP-NDA. The first power line PL1 may extend to the non-display area DP-NDA defined at a left side of the display area DP-DA shown in FIG. 5 through the corner area CNA. In the corner area CNA, a boundary between the display area DP-DA and the non-display area DP-NDA may be a curved line when viewed in the plane. The boundary between the display area DP-DA and the non-display area DP-NDA is indicated by a dotted line in FIG. 8.

The first power line PL1 may extend to the non-display area DP-NDA defined at an upper side of the display area DP-DA and to the non-display area DP-NDA defined at a right side of the display area DP-DA after passing through the non-display area DP-NDA defined at the left side of the display area DP-DA shown in FIG. 5. The second power line PL2 may be located in the non-display area DP-NDA defined at the lower side of the display area DP-DA when viewed in the plane, and may extend in the first direction DR1. The first power line PL1 and the second power line PL2 may be located on the same layer as the third connection pattern CNP3 shown in FIG. 6.

The first voltage line VL1 and the second voltage line VL2 may be arranged in the non-display area DP-NDA. In FIG. 8, one first voltage line VL1 and one second voltage line VL2 are shown, although each of the first voltage line VL1 and the second voltage line VL2 may be provided in plural. The first voltage line VL1 may receive a first voltage, and the second voltage line VL2 may receive a second voltage higher than the first voltage. The first voltage may be the first power supply voltage, and the second voltage may be the second power supply voltage.

The first voltage line VL1 and the second voltage line VL2 may not overlap the second power line PL2, and may be located at a position that is lower than the second power line PL2 when viewed in the plane. The first voltage line VL1 and the second voltage line VL2 may be located more adjacent to an edge EG of the display module DM than the second power line PL2 is. The edge EG of the display module DM may be an edge 110-EG of the base layer 110 shown in FIG. 9. The edge 110-EG of the base layer 110 indicates a side surface of the base layer when viewed in the plane. The first power line PL1 and the second power line PL2 may be located on the same layer as the third connection pattern CNP3 or the first connection pattern CNP1 shown in FIG. 6.

At least one control signal line CSL may be located in the non-display area DP-NDA. The control signal line CSL may be connected to the scan-driving circuit SDC shown in FIG. 5 via the corner area CNA. The control signal line CSL may overlap the first power line PL1 and the second power line PL2. The control signal line CSL may be located on the same layer as one of the first shielding electrode BMLa, the gate GT1 of the silicon transistor S-TFT, the second electrode CE20, or the gate GT2 of the oxide transistor O-TFT shown in FIG. 6.

The data lines DL may be arranged in the display area DP-DA and the non-display area DP-NDA. Among the data lines DL, portions overlapping the display area DP-DA may be located on the same layer as one of the first connection pattern CNP1 or the third connection pattern CNP3 shown in FIG. 6. Among the data lines DL, portions overlapping the non-display area DP-NDA may be located on the same layer as one of the first shielding electrode BMLa, the gate GT1 of the silicon transistor S-TFT, the second electrode CE20, or the gate GT2 of the oxide transistor O-TFT shown in FIG. 6. The portions of the data lines DL, which overlap the display area DP-DA, and the portions of the data lines DL, which overlap the non-display area DP-NDA, may be connected to each other via contact holes defined through the barrier layer 10br, the buffer layer 10bf, and at least one corresponding insulating layer among the insulating layers 10, 20, 30, 40, 50, 60, and 70. Connection portions where the portions of the data lines DL, which overlap the display area DP-DA, and the portions of the data lines DL, which overlap the non-display area DP-NDA, are connected to each other may be located in the non-display area DP-NDA adjacent to the boundary between the display area DP-DA and the non-display area DP-NDA.

The data lines DL may cross the first voltage line VL1, the second voltage line VL2, and the second power line PL2. An electrostatic discharge protection circuit ESD connected to the data line DL, the first voltage line VL1, and the second voltage line VL2 may be located in the non-display area DP-NDA. The electrostatic discharge protection circuit ESD may be located between the first voltage line VL1 and the second voltage line VL2. FIG. 8 shows one electrostatic discharge protection circuit ESD as a representative example. However, the present disclosure should not be limited thereto or thereby. According to one or more embodiments, the electrostatic discharge protection circuit ESD may be connected to each of the data lines DL, or multiple electrostatic discharge protection circuits ESD may be connected to each of the data lines DL.

The second signal lines SL2 may be located in the non-display area DP-NDA. The second signal lines SL2 may overlap the control signal line CSL, and may overlap the first power line PL1 or the second power line PL2. Each of the second signal lines SL2 may be connected to a corresponding electrode among the second electrodes E2-1 to E2-3 located in the display area DP-DA.

FIG. 8 shows an alignment mark AM located in the corner area CNA. The alignment mark AM may be used as a reference point for the alignment of the display module DM and a mask in a deposition process. The alignment mark AM may be located on the same layer as, and may be formed through the same process as, a first pad electrode PD1 described later with reference to FIG. 12.

FIG. 9 is a cross-sectional view of the display module DM taken along the line III-III′ of FIG. 8.

Structures of the base layer 110, the driving element layer 120, the light-emitting element layer 130, the encapsulation layer 140, and the input sensor ISL, which are located in the display area DP-DA, are substantially the same as those described with reference to FIG. 6, and thus, details thereof will be omitted. FIG. 9 schematically shows the silicon transistor S-TFT of the pixel-driving circuit PC of FIG. 6. Each of the barrier layer 10br, the buffer layer 10bf, the insulating layers 10, 20, 30, 40, 50, 60, and 70, and the pixel definition layer PDL described with reference to FIG. 6 may extend from the display area DP-DA to the non-display area DP-NDA. The extended forms of the barrier layer 10br, the buffer layer 10bf, the insulating layers 10, 20, 30, 40, and 50, and the pixel definition layer PDL may vary depending on the layers. Each of the insulating layer 60, the upper insulating layer 70, the encapsulation layer 140, the first insulating layer 210, the second insulating layer 230, and the third insulating layer 250 described with reference to FIG. 6 may extend from the display area DP-DA to the non-display area DP-NDA. The extended forms of the insulating layer 60, the upper insulating layer 70, the encapsulation layer 140, the first insulating layer 210, the second insulating layer 220, and the third insulating layer 250 may vary depending on the layers. Each of the insulating layer 60, the upper insulating layer 70, the encapsulation layer 140, the first insulating layer 210, the second insulating layer 230, and the third insulating layer 250 may be located in a portion of the non-display area DP-NDA.

In one or more embodiments, the pad electrodes and the data line DL may be located in the non-display area DP-NDA, and details thereof will be described with reference to FIG. 12.

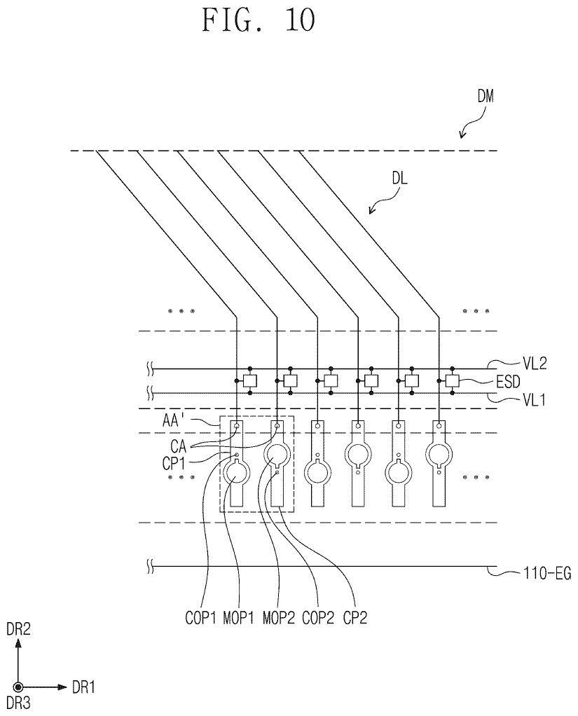

FIG. 10 is an enlarged plan view of the non-display area of the display module according to one or more embodiments of the present disclosure. The non-display area DP-NDA of FIG. 8 is shown further enlarged in FIG. 10. FIG. 10 shows portions of the data lines DL.

Referring to FIG. 10, the first voltage line VL1 and the second voltage line VL2 may be located. The electrostatic discharge protection circuits ESD may be arranged between the first voltage line VL1 and the second voltage line VL2, and may be spaced apart from each other in the first direction DR1. The electrostatic discharge protection circuit ESD may include a first transistor that is diode-connected from the first voltage line VL1 to the data line DL, and a second transistor that is diode-connected from the data line DL to the second voltage line VL2.

Each of the data lines DL may be electrically connected to conductive patterns CP1 and CP2 via a contact hole CA. The contact hole CA may be located adjacent to the first voltage line VL1. However, the present disclosure should not be limited thereto or thereby.

Each of a first conductive pattern CP1 and a second conductive pattern CP2 may be provided in plural. The first conductive pattern CP1 and the second conductive pattern CP2 may be located spaced apart from the first voltage line VL1 in a direction opposite to the second direction DR2. The first conductive patterns CP1 and the second conductive patterns CP2 may be alternately arranged with each other to correspond to the data lines DL in a one-to-one correspondence. The first conductive pattern CP1 may be alternately arranged with the second conductive pattern CP2, and may be arranged spaced apart from each other in the first direction DR1. Positions of the first conductive pattern CP1 and the second conductive pattern CP2 shown in FIG. 10 are merely an example and may be changed.

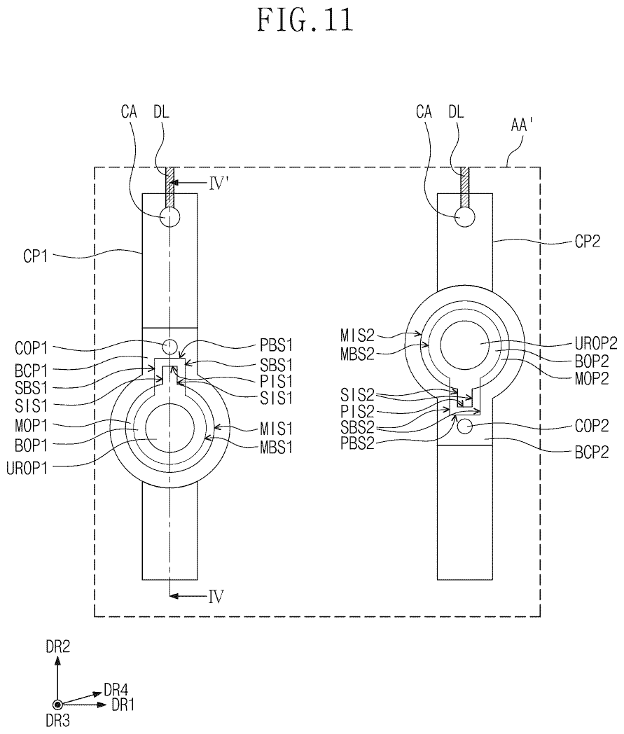

FIG. 11 is an enlarged plan view of an area AA′ of FIG. 10, and FIG. 12 is a cross-sectional view of the display panel taken along the line IV-IV′ of FIG. 11. The buffer layer 10bf, the second insulating layer 20 to the fourth insulating layer 40, and the upper insulating layer 70 described with reference to FIG. 6 are omitted in FIG. 12, and the same descriptions as provided with reference to FIG. 6 may be applied to the omitted components in FIG. 12.

Referring to FIGS. 11 and 12, the base layer 110 may include the first resin layer 110-B1, and the second resin layer 110-B2 located on the first resin layer 110-B1. The base layer 110 may further include a first base insulating layer 110-I1 located between the first resin layer 110-B1 and the second resin layer 110-B2, a second base insulating layer 110-I2 located between the first base insulating layer 110-I1 and the second resin layer 110-B2, a third base insulating layer 110-I3 located between the second base insulating layer 110-I2 and the second resin layer 110-B2, and a fourth base insulating layer 110-I4 between the third base insulating layer 110-I3 and the second resin layer 110-B2. Each of the first base insulating layer 110-I1, the second base insulating layer 110-I2, and the fourth base insulating layer 110-I4 may include silicon oxide (SiOₓ). The third base insulating layer 110-I3 may include amorphous silicon.

The first resin layer 110-B1 may be provided with a lower resin opening LROP defined therethrough. A lower surface of the first pad electrode PD1 may be exposed through the lower resin opening LROP. The flexible circuit board FCB (refer to FIG. 2) may be bonded to the first pad electrode PD1 through the lower resin opening LROP.

Upper resin openings UROP1 and UROP2 may be defined through the second resin layer 110-B2 to overlap the non-display area DP-NDA. The upper resin openings UROP1 and UROP2 may be provided in plural. The upper resin openings UROP1 and UROP2 may include a first upper resin opening UROP1 and a second upper resin opening UROP2. Each of the first upper resin opening UROP1 and the second upper resin opening UROP2 may penetrate through the first base insulating layer 110-I1 to the fourth base insulating layer 110-I4. The second upper resin opening UROP2 may be spaced apart from the first upper resin opening UROP1 in a fourth direction DR4 crossing each of the first direction DR1 and the second direction DR2. The first upper resin opening UROP1 and the second upper resin opening UROP2 may be alternately arranged with each other, and may be staggered with each other in the first direction DR1. Accordingly, the first conductive pattern CP1 and the second conductive pattern CP2 may be efficiently placed in terms of space.

The first pad electrode PD1 may be located between the first resin layer 110-B1 and the second resin layer 110-B2, and may overlap the non-display area DP-NDA. A portion of an upper surface of the first pad electrode PD1 may be exposed through the first upper resin opening UROP1. A portion of the first pad electrode PD1 may be located on the first base insulating layer 110-I1. A portion of the second base insulating layer 110-I2 may be located on the first pad electrode PD1. The first pad electrode PD1 may be provided in plural, and the first pad electrodes PD1 may be arranged spaced apart from each other in the first direction DR1. In one or more embodiments, a second pad electrode may be located between the first resin layer 110-B1 and the second resin layer 110-B2, and may overlap the non-display area DP-NDA. In one or more embodiments, a portion of an upper surface of the second pad electrode may be exposed through the second upper resin opening UROP2. In one or more embodiments, the first pad electrode PD1 and the second pad electrode may be alternately arranged with each other in the first direction DR1. Hereinafter, and in one or more embodiments, the term “pad electrode” (e.g., reference character PD in FIG. 19) may be used as a comprehensive term for the first pad electrode PD1 and the second pad electrode, and the description of the first pad electrode PD1 may be applied equally to the second pad electrode.

The driving element layer 130 may include the barrier layer 10br, the data line DL, the conductive patterns CP1 and CP2, the insulating layer 60, and bridge conductive patterns BCP1 and BCP2.

The barrier layer 10br may be located on the second resin layer 110-B2. The barrier layer 10br may be located directly on the second resin layer 110-B2. The barrier layer 10br may be provided with (e.g., may define) barrier openings BOP1 and BOP2 defined therethrough to correspond to the upper resin openings UROP1 and UROP2. The barrier openings BOP1 and BOP2 may include a first barrier opening BOP1 overlapping the first upper resin opening UROP1, and a second barrier opening BOP2 overlapping the second upper resin opening UROP2.

The first upper resin opening UROP1 may have a size that is smaller than a size of the first barrier opening BOP1 when viewed in the plane. The first barrier opening BOP1 may be defined by a first protrusion barrier side surface PBS1 and a first main barrier side surface MBS1. The first protrusion barrier side surface PBS1 may be substantially parallel to the first direction DR1. The first barrier opening BOP1 may be defined by the first protrusion barrier side surface PBS1, the first main barrier side surface MBS1, and a first sub-barrier side surface SBS1 connecting the first protrusion barrier side surface PBS1 and the first main barrier side surface MBS1.

The first sub-barrier side surface SBS1 may be substantially parallel to the second direction DR2. The first protrusion barrier side surface PBS1 may be adjacent to the contact hole CA. The first protrusion barrier side surface PBS1 may be located between the first main barrier side surface MBS1 and the contact hole CA. The first main barrier side surface MBS1 may surround a portion of the first upper resin opening UROP1. The first main barrier side surface MBS1 may surround the first upper resin opening UROP1 except portions surrounded by the first protrusion barrier side surface PBS1 and the first sub-barrier side surface SBS1 (e.g., the main barrier side surface MBS1 may generally have a same shape as, or may follow a contour of, the first upper resin opening UROP1). A distance from the first protrusion barrier side surface PBS1 to a center of the first upper resin opening UROP1 may be greater than a distance from the first main barrier side surface MBS1 to the center of the first upper resin opening UROP1. The first upper resin opening UROP1 may have a size that is smaller than the size of the first barrier opening BOP1 when viewed in the plane.

The second barrier opening BOP2 may be defined by a second protrusion barrier side surface PBS2 and a second main barrier side surface MBS2. The second protrusion barrier side surface PBS2 may be substantially parallel to the first direction DR1. The second barrier opening BOP2 may be defined by the second protrusion barrier side surface PBS2, the second main barrier side surface MBS2, and a second sub-barrier side surface SBS2 connecting the second protrusion barrier side surface PBS2 and the second main barrier side surface MBS2. The second sub-barrier side surface SBS2 may be substantially parallel to the second direction DR2. The second protrusion barrier side surface PBS2 may be adjacent to the contact hole CA. The second protrusion barrier side surface PBS2 may be located between the second main barrier side surface MBS2 and a contact opening COP2 (described below).

The second main barrier side surface MBS2 may surround a portion of the second upper resin opening UROP2. The second main barrier side surface MBS2 may surround the second upper resin opening UROP2 except portions surrounded by the second protrusion barrier side surface PBS2 and the second sub-barrier side surface SBS2. A distance from the second protrusion barrier side surface PBS2 to a center of the second upper resin opening UROP2 may be greater than a distance from the second main barrier side surface MBS2 to the center of the second upper resin opening UROP2.

The data line DL may be located on the barrier layer 10br. The data line DL may be located on the first insulating layer 10 in the non-display area DP-NDA. The data line DL may overlap each of the display area DP-DA (refer to FIG. 5) and the non-display area DP-NDA. The data line DL may not overlap, or may be separated from (in plan view), the upper resin openings UROP1 and UROP2 or the barrier openings BOP1 and BOP2.

The fifth insulating layer 50 may be located on the data line DL in the non-display area DP-NDA. The fifth insulating layer 50 may be located directly on the data line DL in the non-display area DP-NDA. The contact hole CA may be defined through the fifth insulating layer 50 to expose the portion of the data line DL. The contact hole CA may have a size that is smaller than the size of the upper resin openings UROP1 and UROP2 when viewed in the plane. The contact hole CA may be located between the upper resin openings UROP1 and UROP2 and the display area DP-DA.

The conductive patterns CP1 and CP2 may include the first conductive pattern CP1 and the second conductive pattern CP2. The following descriptions on the first conductive pattern CP1 may be applied equally to the second conductive pattern CP2. The first conductive pattern CP1 may include a first pad conductive portion PCP1 and a first data conductive portion DCP1. The first pad conductive portion PCP1 may be located in the first upper resin opening UROP1, and may be in contact with the first pad electrode PD1. The first data conductive portion DCP1 may be in contact with the data line DL. The first conductive pattern CP1 may further include a first extra conductive portion LCP1. The first data conductive portion DCP1 may be located between the first pad conductive portion PCP1 and the first extra conductive portion LCP1.

The insulating layer 60 may be located on the conductive patterns CP1 and CP2. The insulating layer 60 may overlap a boundary between the first pad conductive portion PCP1 and the first data conductive portion DCP1. The insulating layer 60 may be provided with/may define connection openings COP1 and COP2 defined therethrough, and main openings MOP1 and MOP2 defined therethrough. A first connection opening COP1 may be formed between the first upper resin opening UROP1 and the display area DP-DA (refer to FIG. 5). The second upper resin opening UROP2 may be formed between a second connection opening COP2 and the display area DP-DA (refer to FIG. 5). The connection openings COP1 and COP2 may include the first connection opening COP1 and the second connection opening COP2. The main openings MOP1 and MOP2 may include a first main opening MOP1 and a second main opening MOP2. The following descriptions on the first connection opening COP1 may be applied equally to the second connection opening COP2, and the following descriptions on the first main opening MOP1 may be applied equally to the second main opening MOP2.

A portion of the first data conductive portion DCP1 may be exposed through the first connection opening COP1. The first main opening MOP1 may overlap the first upper resin opening UROP1. A portion of the first pad conductive portion PCP1 may be exposed through the first main opening MOP1. The main openings MOP1 and MOP2 may be defined by protrusion insulating side surfaces PIS1 and PIS2 and main insulating side surfaces MIS1 and MIS2. The main openings MOP1 and MOP2 may be defined by the protrusion insulating side surfaces PIS1 and PIS2, the main insulating side surfaces MIS1 and MIS2, and sub-insulating side surfaces SIS1 and SIS2 connecting the protrusion insulating side surfaces PIS1 and PIS2 and the main insulating side surfaces MIS1 and MIS2.

The first main opening MOP1 may be defined by a first protrusion insulating side surface PIS1 and a first main insulating side surface MIS1. The first main opening MOP1 may be defined by the first protrusion insulating side surface PIS1, the first main insulating side surface MIS1, and a first sub-insulating side surface SIS1. The second main opening MOP2 may be defined by a second protrusion insulating side surface PIS2 and a second main insulating side surface MIS2. The second main opening MOP2 may be defined by the second protrusion insulating side surface PIS2, the second main insulating side surface MIS2, and a second sub-insulating side surface SIS2. The first upper resin opening UROP1 may have a size that is greater than a size of the first connection opening COP1 when viewed in the plane. The first connection opening COP1 may be spaced apart from the first upper resin opening UROP1 in the second direction DR2. The second connection opening COP2 may be spaced apart from the second upper resin opening UROP2 in the direction opposite to the second direction DR2.

The first protrusion insulating side surface PIS1 may be adjacent to the contact hole CA. The first protrusion insulating side surface PIS1 may be located between the first main insulating side surface MIS1 and the contact hole CA. The first main insulating side surface MIS1 may surround a portion of the first upper resin opening UROP1 (e.g., in plan view). A separation distance between the first main insulating side surface MIS1 and the center of the first upper resin opening UROP1 may be less than a separation distance between the first protrusion insulating side surface PIS1 and the center of the first upper resin opening UROP1.

The second protrusion insulating side surface PIS2 may be adjacent to the contact hole CA. The second protrusion insulating side surface PIS2 may be located between the second main insulating side surface MIS2 and the contact hole CA. The second main insulating side surface MIS2 may surround a portion of the second upper resin opening UROP2 (e.g., in plan view). A separation distance between the second main insulating side surface MIS2 and the center of the second upper resin opening UROP2 may be less than a separation distance between the second protrusion insulating side surface PIS2 and the center of the second upper resin opening UROP2.

The bridge conductive patterns BCP1 and BCP2 may include a first bridge conductive pattern BCP1 and a second bridge conductive pattern BCP2. The following descriptions on the first bridge conductive pattern BCP1 may be applied equally to the second bridge conductive pattern BCP2. The first bridge conductive pattern BCP1 may be located on the first conductive pattern CP1 and the insulating layer 60. The first bridge conductive pattern BCP1 may be in contact with the first pad conductive portion PCP1 through the first upper resin opening UROP1, and may be in contact with the first data conductive portion DCP1 through the first connection opening COP1. The first bridge conductive pattern BCP1 may electrically connect the first pad conductive portion PCP1 and the first data conductive portion DCP1.

The first protrusion barrier side surface PBS1 may be located between the first protrusion insulating side surface PIS1 and the first connection opening COP1. The first main insulating side surface MIS1 may overlap the first main barrier side surface MBS1 when viewed in the plane.

The second protrusion barrier side surface PBS2 may be located between the second protrusion insulating side surface PIS2 and the second connection opening COP2. The second main insulating side surface MIS2 may overlap the second main barrier side surface MBS2 when viewed in the plane.

According to the display panel DP of the present disclosure, different from a conventional display panel, the barrier layer 10br includes the first protrusion barrier side surface PBS1, and the distance from the first protrusion barrier side surface PBS1 to the center of the first upper resin opening UROP1 is greater than the distance from the first main barrier side surface MBS1 to the center of the first upper resin opening UROP1, and thus, the space where the insulating layer 60 covers the boundary between the first pad conductive portion PCP1 and the first data conductive portion DCP1 may be secured. When the insulating layer 60 does not cover the boundary between the first pad conductive portion PCP1 and the first data conductive portion DCP1, the first bridge conductive pattern BCP1 may be disconnected due to a step difference between the first pad conductive portion PCP1 and the first data conductive portion DCP1, and the reliability of the display panel may be degraded.

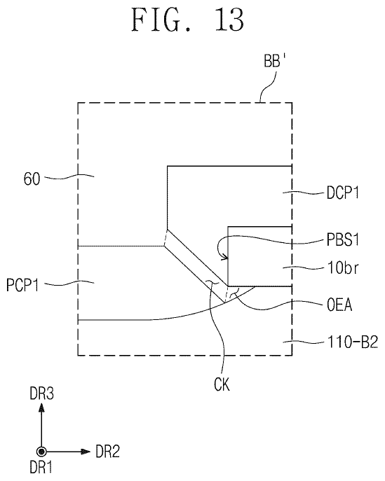

When the insulating layer 60 covers the boundary between the first pad conductive portion PCP1 and the first data conductive portion DCP1, and when the first bridge conductive pattern BCP1 is located on the insulating layer 60 covering the first pad conductive portion PCP1 and the first data conductive portion DCP1, the first bridge conductive pattern BCP1 may electrically connect the first pad conductive portion PCP1 and the first data conductive portion DCP1 without being disconnected, thereby improving the reliability of the display panel. Hereinafter, the boundary between the first pad conductive portion PCP1 and the first data conductive portion DCP1 will be described in detail with reference to FIG. 13.

FIG. 13 is an enlarged plan view of an area BB′ of FIG. 12. FIG. 13 is an enlarged view of the area BB adjacent to the first pad conductive portion PCP1 and the first data conductive portion DCP1.

Referring to FIGS. 12 and 13, the first pad conductive portion PCP1 and the first data conductive portion DCP1 may be spaced apart from each other, and may not be in contact with each other. A portion of the second resin layer 110-B2 may be etched during a process of forming the first barrier opening BOP1, and as a result, an over-etched area OEA where the lower surface of the barrier layer 10br is partially exposed may be formed. When a conductive material is coated on the second resin layer 110-B2 and the barrier layer 10br to form the first conductive pattern CP1, a separation portion CK may be formed between the first pad conductive portion PCP1 located on the second resin layer 110-B2 and the first data conductive portion DCP1, due to the over-etched area OEA. The separation portion CK may be a space that allows the first pad conductive portion PCP1 and the first data conductive portion DCP1 to be separated from each other. The first pad conductive portion PCP1 and the first data conductive portion DCP1 may not be electrically connected to each other, or may be electrically insulated/separated, due to the separation portion CK. The separation portion CK may also be formed between the first extra conductive portion LCP1 and the first pad conductive portion PCP1.

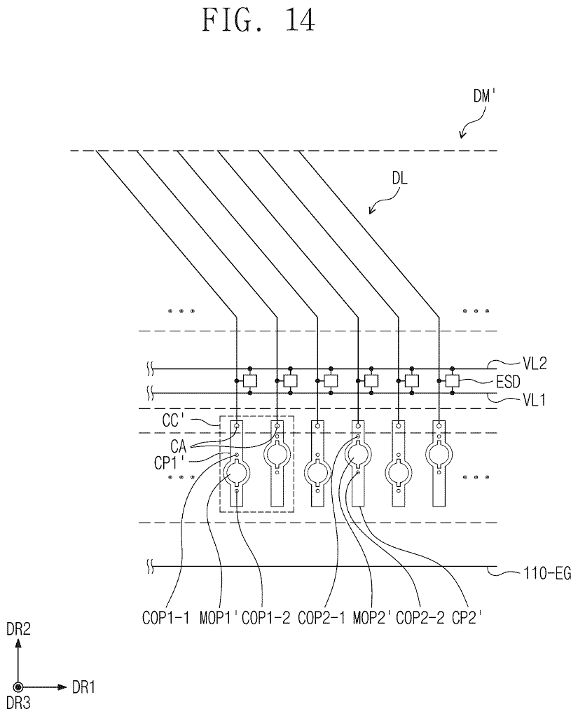

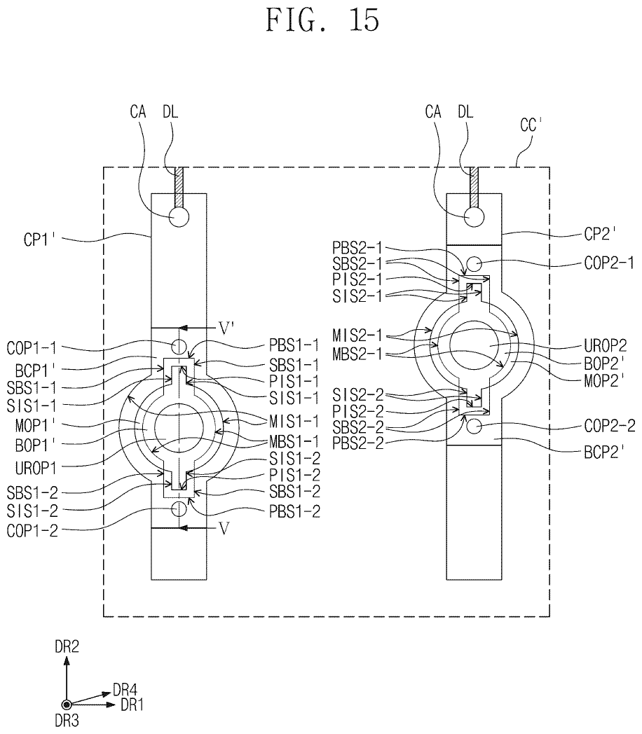

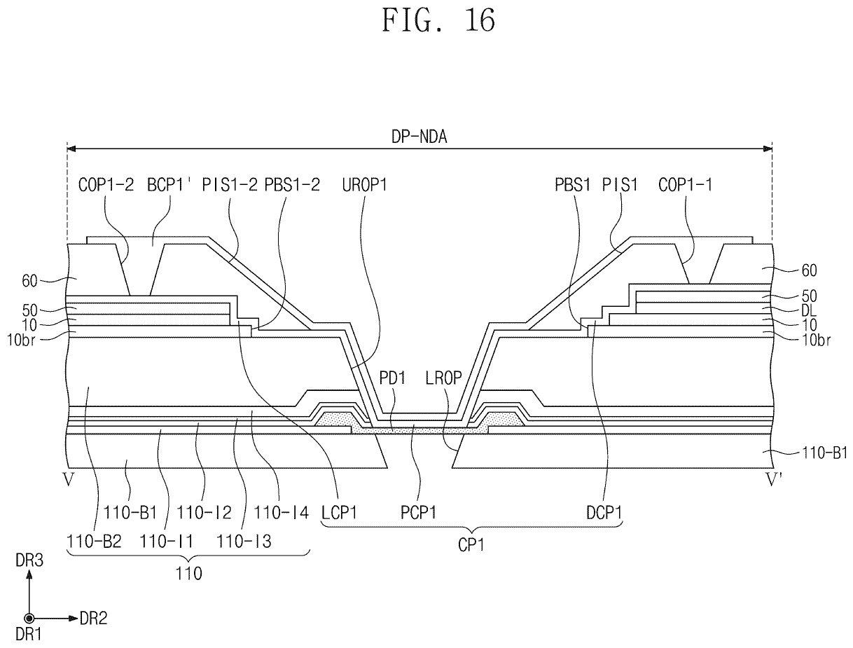

FIG. 14 is an enlarged plan view of a non-display area of a display module DM′ according to one or more embodiments of the present disclosure. FIG. 15 is an enlarged plan view of an area CC′ of FIG. 14. FIG. 16 is a cross-sectional view of a display panel taken along the line V-V′ of FIG. 15.

In FIGS. 14 to 16, the same reference numerals denote the same elements in FIGS. 10 to 12, and thus, detailed descriptions of the same elements will be omitted.

Referring to FIGS. 14 and 15, a first connection opening (refer to COP1 of FIG. 11) may include a first-first connection opening COP1-1 and a first-second connection opening COP1-2. The first-first connection opening COP1-1 may be adjacent to a display area (refer to DP-DA of FIG. 5). The first-second connection opening COP1-2 may be spaced apart from the first-first connection opening COP1-1 with a first upper resin opening UROP1 interposed therebetween. The first-first connection opening COP1-1 may be spaced apart from the first upper resin opening UROP1 in the second direction DR2. The first-second connection opening COP1-2 may be spaced apart from the first upper resin opening UROP1 in the direction opposite to the second direction DR2. A first barrier opening BOP1′, a first main opening MOP1′, and the first upper resin opening UROP1 may be defined between the first-first connection opening COP1-1 and the first-second connection opening COP1-2.

The first barrier opening BOP1′ may be defined by a first-first protrusion barrier side surface PBS1-1, a first-first main barrier side surface MBS1-1, and a first-second protrusion barrier side surface PBS1-2. The first-first protrusion barrier side surface PBS1-1 may be adjacent to the first-first connection opening COP1-1. The first-second protrusion barrier side surface PBS1-2 may be adjacent to the first-second connection opening COP1-2. The first-first protrusion barrier side surface PBS1-1 may be connected to the first-first main barrier side surface MBS1-1 by a first-first sub-barrier side surface SBS1-1. The first-second protrusion barrier side surface PBS1-2 may be connected to the first-first main barrier side surface MBS1-1 by a first-second sub-barrier side surface SBS1-2.

The first main opening MOP1′ may be defined by a first-first protrusion insulating side surface PIS1-1, a first-first main insulating side surface MIS1-1, and a first-second protrusion insulating side surface PIS1-2. The first-first protrusion insulating side surface PIS1-1 may be adjacent to the first-first connection opening COP1-1. The first-second protrusion insulating side surface PIS1-2 may be adjacent to the first-second connection opening COP1-2. The first-first protrusion insulating side surface PIS1-1 may be connected to the first-first main insulating side surface MIS1-1 by a first-first sub-insulating side surface SIS1-1. The first-second protrusion insulating side surface PIS1-2 may be connected to the first-first main insulating side surface MIS1-1 by a first-second sub-insulating side surface SIS1-2.

A second connection opening (refer to COP2 of FIG. 11) may include a second-first connection opening COP2-1 and a second-second connection opening COP2-2. The second-first connection opening COP2-1 may be adjacent to the display area (refer to DP-DA of FIG. 5). The second-second connection opening COP2-2 may be spaced apart from the second-first connection opening COP2-1 with a second upper resin opening UROP2 interposed therebetween. A second barrier opening BOP2′, a second main opening MOP2′, and the second upper resin opening UROP2 may be defined between the second-first connection opening COP2-1 and the second-second connection opening COP2-2.

The second barrier opening BOP2′ may be defined by a second-first protrusion barrier side surface PBS2-1, a second-first main barrier side surface MBS2-1, and a second-second protrusion barrier side surface PBS2-2. The second-first protrusion barrier side surface PBS2-1 may be adjacent to the second-first connection opening COP2-1. The second-second protrusion barrier side surface PBS2-2 may be adjacent to the second-second connection opening COP2-2. The second-first protrusion barrier side surface PBS2-1 may be connected to the second-first main barrier side surface MBS2-1 by a second-first sub-barrier side surface SBS2-1. The second-second protrusion barrier side surface PBS2-2 may be connected to the second-first main barrier side surface MBS2-1 by a second-second sub-barrier side surface SBS2-2.

The second main opening MOP2′ may be defined by a second-first protrusion insulating side surface PIS2-1, a second-first main insulating side surface MIS2-1, and a second-second protrusion insulating side surface PIS2-2. The second-first protrusion insulating side surface PIS2-1 may be adjacent to the second-first connection opening COP2-1. The second-second protrusion insulating side surface PIS2-2 may be adjacent to the second-second connection opening COP2-2. The second-first protrusion insulating side surface PIS2-1 may be connected to the second-first main insulating side surface MIS2-1 by a second-first sub-insulating side surface SIS2-1. The second-second protrusion insulating side surface PIS2-2 may be connected to the second-first main insulating side surface MIS2-1 by a second-second sub-insulating side surface SIS2-2.

Referring to FIG. 16, different from the display panel shown in FIG. 12, the first-first connection opening COP1-1 and the first-second connection opening COP1-2 may be defined through an insulating layer 60. The descriptions on the first connection opening COP1 in FIG. 12 may be applied equally to the first-first connection opening COP1-1. A portion of an upper surface of a first extra conductive portion LCP1 may be exposed through the first-second connection opening COP1-2. A first bridge conductive pattern BCP1′ may be in contact with the first extra conductive portion LCP1 through the first-second connection opening COP1-2. The first bridge conductive pattern BCP1′ may electrically connect the first extra conductive portion LCP1, a first pad conductive portion PCP1, and a first data conductive portion DCP1. When compared to the display panel shown in FIG. 12, both the first-first connection opening COP1-1 and the first-second connection opening COP1-2 may be defined through the insulating layer 60, and thus, an area where the first bridge conductive pattern BCP1′ contacts a first conductive pattern CP1 may increase. As a result, the transmission of electrical signals may be smoother.

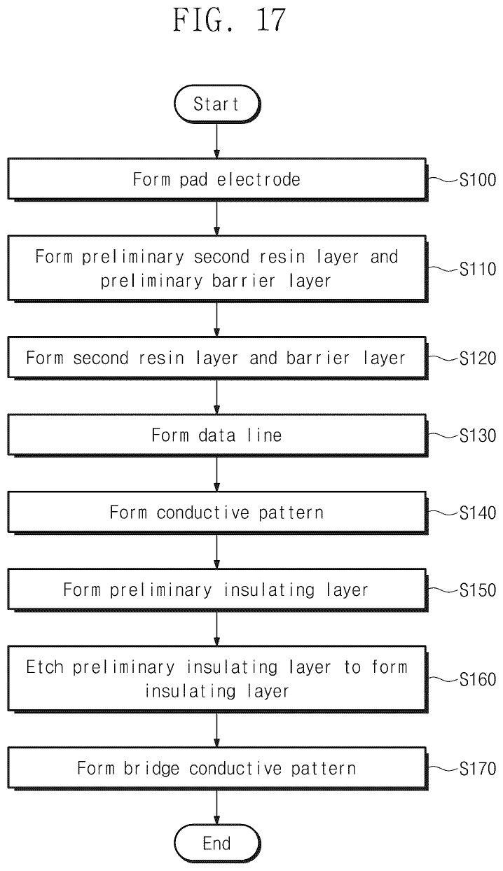

Hereinafter, a method of manufacturing the display panel will be described with reference to FIGS. 17 to 25. Details of the components described with reference to FIGS. 1 to 16 are omitted.

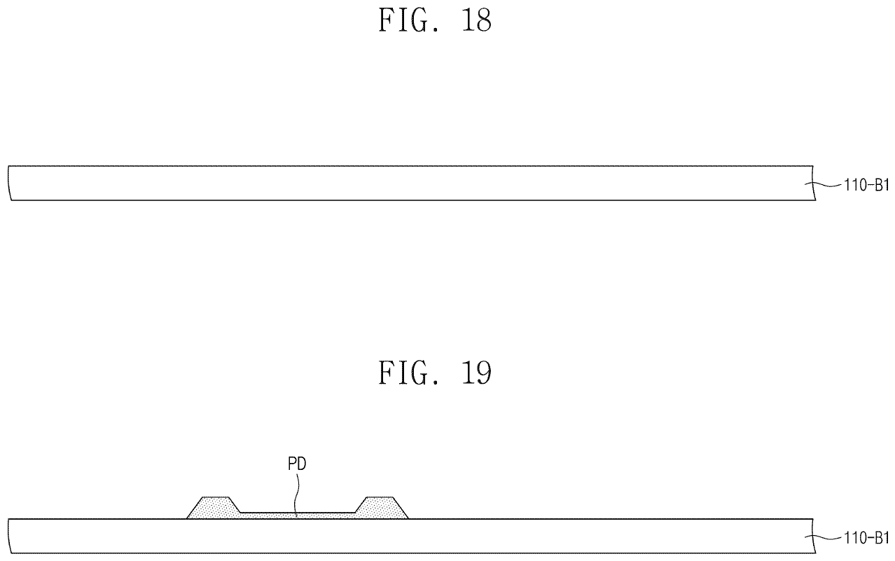

FIG. 17 is a flowchart illustrating the method of manufacturing the display panel according to one or more embodiments of the present disclosure. FIGS. 18 to 25 are views illustrating processes of the method of manufacturing the display panel according to one or more embodiments of the present disclosure.

Referring to FIG. 17, the manufacturing method of the display panel may include forming the pad electrode (S100), forming a preliminary second resin layer and a preliminary barrier layer (S110), forming the second resin layer and the barrier layer (S120), forming the data line (S130), forming the conductive pattern (S140), forming a preliminary insulating layer (S150), etching a portion of the preliminary insulating layer to form the insulating layer (S160), and forming the bridge conductive pattern (S170). As used herein, “forming” or “form” may mean “providing” or “provide,” as appropriate.

Referring to FIGS. 18 and 19, the pad electrode PD may be formed on the first resin layer 110-B1 in the forming of the pad electrode PD. The description on the first pad electrode PD1 with reference to FIG. 12 may be applied equally to the pad electrode PD.

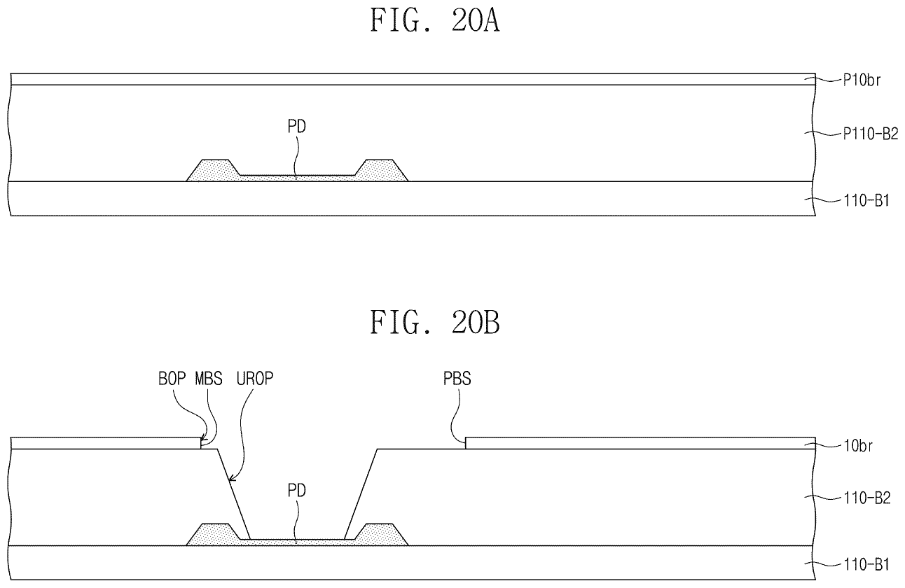

Referring to FIG. 20A, in the forming of the preliminary second resin layer P110-B2 and the preliminary barrier layer P10br, the preliminary second resin layer P110-B2 may be located on the first resin layer 110-B1 and may cover the pad electrode PD. The preliminary barrier layer P10br may be located on the preliminary second resin layer P110-B2. The preliminary second resin layer P110-B2 may include the same material as the second resin layer 110-B2 described in FIG. 12. The preliminary barrier layer P10br may include the same material as the barrier layer 10br described in FIG. 12.

Referring to FIG. 20B, in the forming of the second resin layer 110-B2 and the barrier layer 10br, the upper resin opening UROP may be formed through the second resin layer 110-B2 to expose the portion of the upper surface of the pad electrode PD. The description on the first upper resin opening UROP1 with reference to FIG. 12 may be applied equally to the upper resin opening UROP. The barrier opening BOP may be defined through the barrier layer 10br to overlap the upper resin opening UROP. Although the same etching process is performed in the process of forming the barrier opening BOP, because the degree to which the second resin layer 110-B2 is etched is greater than the degree to which the preliminary barrier layer P10br is etched, a portion of the second resin layer 110-B2 may be etched together, and thus, the over-etched area OEA described with reference to FIG. 13 may be formed.

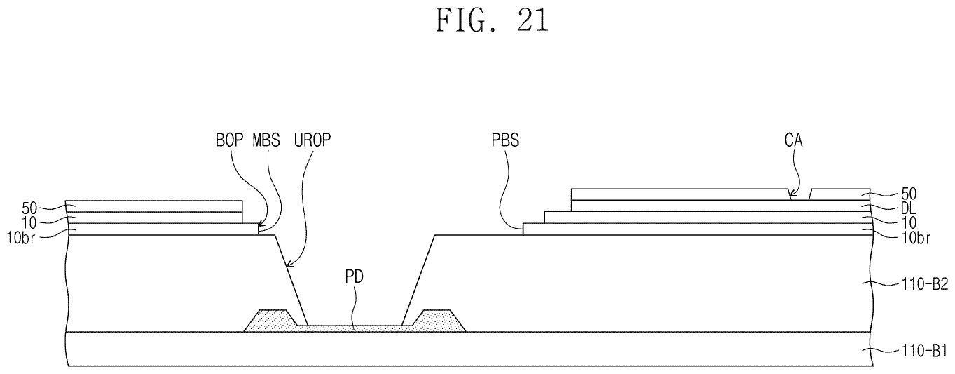

Referring to FIG. 21, in the forming of the data line DL, the data line DL may be formed adjacent to the display area DP-NDA (refer to FIG. 5). The forming of the data line DL may include forming the fifth insulating layer 50 through which the contact hole CA is defined. One end of the fifth insulating layer 50 may be aligned with one end of the data line DL.

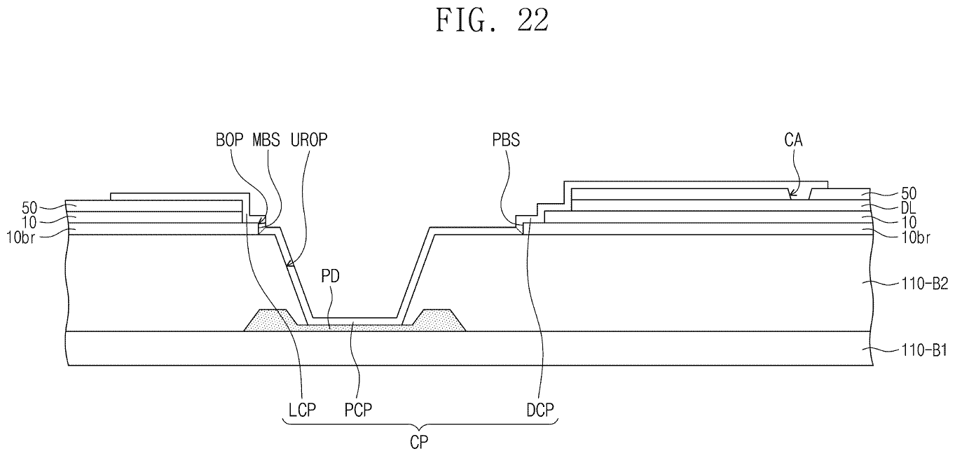

Referring to FIG. 22, in the forming of the conductive pattern CP, the conductive pattern CP may include the pad conductive portion PCP that is located in the upper resin opening UROP and in contact with the pad electrode PD and the data conductive portion DCP that contacts the data line DL through the contact hole CA. The conductive pattern CP may further include the extra conductive portion LCP that is spaced apart from the data conductive portion DCP. The pad conductive portion PCP may be located between the data conductive portion DCP and the extra conductive portion LCP. The description on the first conductive pattern CP1 with reference to FIG. 12 may be applied equally to the conductive pattern CP. The descriptions on the first pad conductive portion PCP1, the first data conductive portion DCP1, and the first extra conductive portion LCP1 with reference to FIG. 12 may be applied equally to the pad conductive portion PCP, the data conductive portion DCP, and the extra conductive portion LCP.

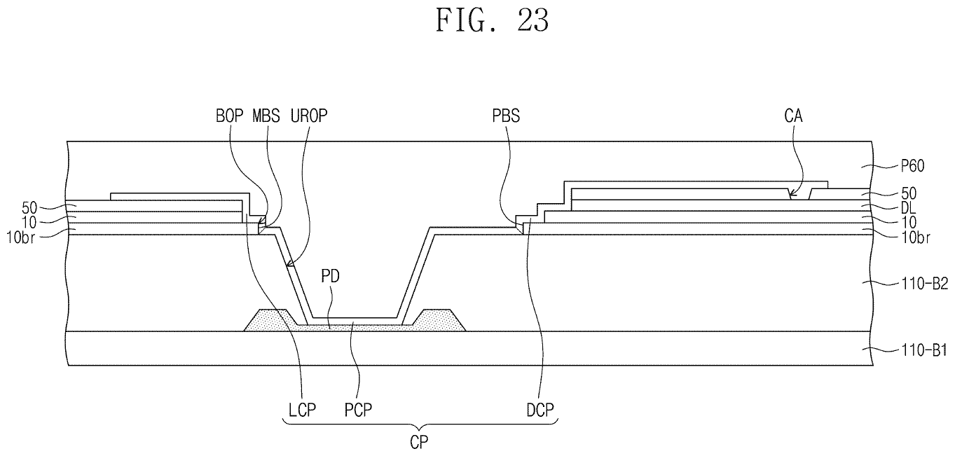

Referring to FIG. 23, the preliminary insulating layer P60 may include the same material as the insulating layer 60 described with reference to FIG. 5 in the forming of the preliminary insulating layer P60. The preliminary insulating layer P60 may be located on the fifth insulating layer 50 and the conductive pattern CP and may cover the conductive pattern CP.

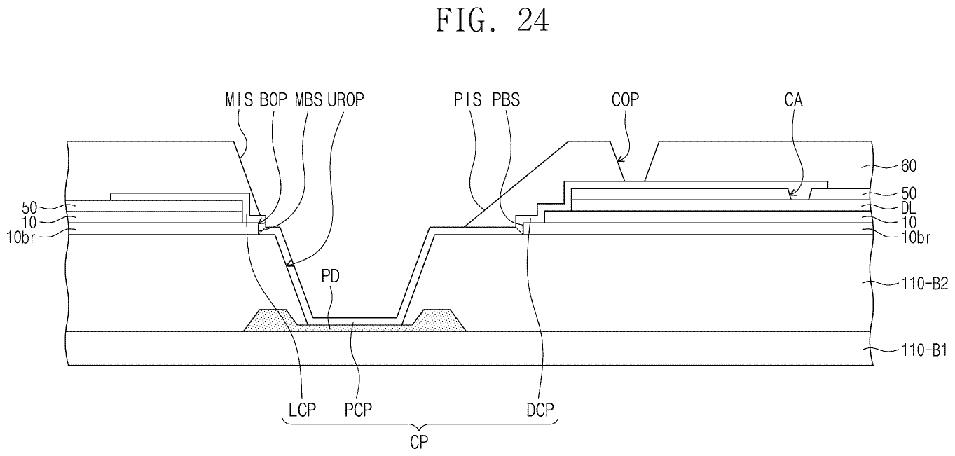

Referring to FIG. 24, in one or more embodiments, in the etching of the portion of the preliminary insulating layer P60 to form the insulating layer 60, the connection opening COP through which the portion of the data conductive portion DCP is exposed, and the main opening overlapping the upper resin opening UROP, may be formed through the insulating layer 60. The main opening may be defined by the main insulating side surface MIS and the protrusion insulating side surface PIS. The descriptions on the first connection opening COP1 and the first main opening MOP1 with reference to FIG. 12 may be applied equally to the connection opening COP and the main opening.

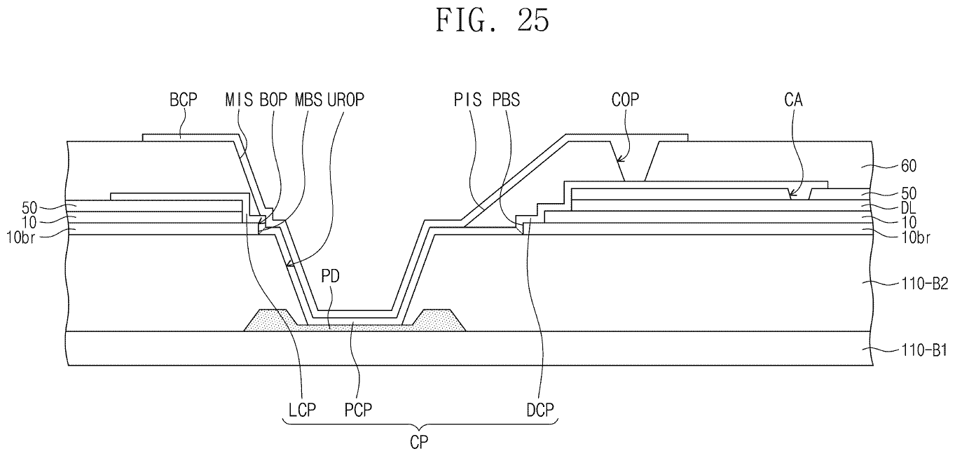

Referring to FIG. 25, in the forming of the bridge conductive pattern BCP, the bridge conductive pattern BCP may be located on the conductive pattern CP and the insulating layer 60. The insulating layer 60 may cover the boundary between the pad conductive portion PCP and the data conductive portion DCP, and the bridge conductive pattern BCP may be located on the insulating layer 60 that covers the boundary between the pad conductive portion PCP and the data conductive portion DCP. Accordingly, the bridge conductive pattern BCP may not be disconnected, and may electrically connect the pad conductive portion PCP and the data conductive portion DCP, and thus, the reliability of the display panel may be improved.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present present disclosure shall be determined according to the attached claims, with functional equivalents thereof to be included therein.

1 what is claimed is:

1. A display panel comprising:
a display area;
a non-display area adjacent to the display area;
a base layer comprising a first resin layer overlapping the display area and the non-display area, and a second resin layer above the first resin layer and defining an upper resin opening overlapping the non-display area;
a pad electrode between the first resin layer and the second resin layer, overlapping the non-display area, and having a portion of an upper surface exposed through the upper resin opening;
a driving element layer comprising:
a barrier layer above the second resin layer, and defining a barrier opening overlapping the upper resin opening;
a data line above the barrier layer;
a conductive pattern comprising a pad conductive portion in the upper resin opening and contacting the pad electrode, and a data conductive portion contacting the data line;
an insulating layer above the conductive pattern, defining a connection opening exposing a portion of the data conductive portion, and defining a main opening overlapping the upper resin opening; and
a bridge conductive pattern above the conductive pattern and the insulating layer, contacting the pad conductive portion through the upper resin opening, and contacting the data conductive portion through the connection opening; and
a display element layer comprising a light-emitting element above the second resin layer overlapping the display area, and a transistor electrically connected to the light-emitting element and to the data line,
wherein the barrier opening is defined by a protrusion barrier side surface adjacent to the connection opening, and by a main barrier side surface surrounding a portion of the upper resin opening in plan view,
wherein the main opening is defined by a protrusion insulating side surface adjacent to the connection opening, and by a main insulating side surface surrounding a portion of the upper resin opening in plan view and overlapping the main barrier side surface in plan view, and
wherein the protrusion barrier side surface is between the protrusion insulating side surface and the connection opening.

2. The display panel of claim 1, further comprising a first base insulating layer between the first resin layer and the second resin layer, and below a portion of the pad electrode.

3. The display panel of claim 2, further comprising a second base insulating layer between the first base insulating layer and the second resin layer, and having a portion above the pad electrode.

4. The display panel of claim 3, wherein the first base insulating layer and the second base insulating layer comprise silicon oxide.

5. The display panel of claim 1, wherein the upper resin opening has a size that is greater than a size of the connection opening in plan view.

6. The display panel of claim 1, wherein the upper resin opening has a size that is smaller than a size of the main opening in plan view.

7. The display panel of claim 1, wherein the insulating layer overlaps a boundary between the pad conductive portion and the data conductive portion.

8. The display panel of claim 1, wherein a distance from the protrusion barrier side surface to a center of the upper resin opening is greater than a distance from the main barrier side surface to the center of the upper resin opening.

9. The display panel of claim 1, wherein the barrier layer comprises at least one of silicon oxide or silicon nitride.

10. The display panel of claim 1, wherein the barrier opening is defined by the protrusion barrier side surface, the main barrier side surface, and a sub-barrier side surface connecting the protrusion barrier side surface and the main barrier side surface,
wherein the protrusion barrier side surface is substantially parallel to a first direction, and
wherein the sub-barrier side surface is substantially parallel to a second direction crossing the first direction.

11. The display panel of claim 1, wherein the pad electrode is provided in plural, the pad electrodes being spaced apart in a first direction.

12. The display panel of claim 11, wherein the upper resin opening is provided in plural, portions of upper surfaces of the pad electrodes being exposed through the upper resin openings.

13. The display panel of claim 1, wherein the connection opening is between the upper resin opening and the display area.

14. The display panel of claim 1, wherein the upper resin opening is between the connection opening and the display area.

15. The display panel of claim 1, wherein the upper resin opening comprises a first upper resin opening and a second upper resin opening spaced apart from the first upper resin opening in a fourth direction crossing a first direction and a second direction that crosses the first direction, and
wherein the connection opening comprises a first connection opening spaced apart from the first upper resin opening in the second direction, and a second connection opening spaced apart from the second upper resin opening in a direction opposite to the second direction.

16. The display panel of claim 1, wherein the connection opening comprises:
a first-first connection opening adjacent to the display area; and
a first-second connection opening spaced apart from the first-first connection opening with the upper resin opening therebetween in plan view.

17. An electronic device comprising:
a flexible circuit board; and
a display panel above the flexible circuit board, and comprising:
a display area;
a non-display area adjacent to the display area;
a base layer comprising a first resin layer overlapping the display area and the non-display area and defining a lower resin opening, and a second resin layer above the first resin layer and defining an upper resin opening overlapping the non-display area;
a pad electrode between the first resin layer and the second resin layer, overlapping the non-display area, having a portion of a lower surface contacting the flexible circuit board through the lower resin opening, and having a portion of an upper surface exposed through the upper resin opening;
a driving element layer comprising:
a barrier layer above the second resin layer and defining a barrier opening overlapping the upper resin opening;
a data line above the barrier layer;
a conductive pattern comprising a pad conductive portion in the upper resin opening and contacting the pad electrode, and a data conductive portion contacting the data line;
an insulating layer above the conductive pattern, defining a connection opening exposing a portion of the data conductive portion, and defining a main opening overlapping the upper resin opening; and
a bridge conductive pattern above the conductive pattern and the insulating layer, contacting the pad conductive portion through the upper resin opening, and contacting the data conductive portion through the connection opening; and
a display element layer comprising a light-emitting element above the second resin layer, overlapping the display area, and electrically connected to the data line,
wherein the barrier opening is defined by a protrusion barrier side surface adjacent to the connection opening, and by a main barrier side surface surrounding a portion of the upper resin opening in plan view,
wherein the main opening is defined by a protrusion insulating side surface adjacent to the connection opening, and by a main insulating side surface surrounding a portion of the upper resin opening in plan view and overlapping the main barrier side surface in plan view, and
wherein the protrusion insulating side surface is between the protrusion barrier side surface and the upper resin opening.

18. The electronic device of claim 17, wherein the display element layer further comprises a transistor electrically connected to the light-emitting element and to the data line.

19. The electronic device of claim 17, wherein the data line overlaps the display area and the non-display area.

20. A method of manufacturing a display panel, comprising:
providing a pad electrode on a first resin layer;
providing a preliminary second resin layer above the first resin layer, and covering the pad electrode;
providing a preliminary barrier layer above the preliminary second resin layer;
etching a portion of the preliminary second resin layer to provide a second resin layer defining an upper resin opening to expose a portion of an upper surface of the pad electrode;
etching a portion of the preliminary barrier layer to provide a barrier layer defining a barrier opening overlapping the upper resin opening;
providing a data line above the barrier layer;
providing a conductive pattern comprising a pad conductive portion in the upper resin opening and contacting the pad electrode, and a data conductive portion contacting the data line;
providing a preliminary insulating layer above the conductive pattern;
etching a portion of the preliminary insulating layer to provide an insulating layer above the conductive pattern, defining a connection opening exposing a portion of the data conductive portion, and defining a main opening overlapping the upper resin opening; and
providing a bridge conductive pattern above the conductive pattern and the insulating layer to contact the pad conductive portion through the upper resin opening, and to contact the data conductive portion through the connection opening,
wherein the barrier opening is defined by a protrusion barrier side surface adjacent to the connection opening, and by a main barrier side surface surrounding a portion of the upper resin opening in plan view,
wherein the main opening is defined by a protrusion insulating side surface adjacent to the connection opening, and a main insulating side surface surrounding a portion of the upper resin opening and overlapping the main barrier side surface in plan view, and
wherein the protrusion barrier side surface is between the protrusion insulating side surface and the connection opening.
